(19) United States
(12) Patent Application Publication
(10) Pub. No.: US 2023/0420466 A1
(43) Pub. Date: Dec. 28, 2023

(54) METHODS AND SYSTEMS FOR INFRARED SENSING

(71) Applicant: TriEye Ltd., Tel Aviv (IL)

(72) Inventors: Eran Katzir, Tel Aviv (IL); Matan Assaf, Tel Aviv (IL); Omer Kapach, Tel Aviv (IL); Avraham Bakal, Tel Aviv (IL); Uriel Levy, Tel Aviv (IL)

(21) Appl. No.: 18/253,930

(22) PCT Filed: Nov. 27, 2021
(86) PCT No.: PCT/IB2021/061033

§ 371 Date: May 23, 2023

Related U.S. Application Data
(60) Provisional application No. 63/194,977, filed on May 29, 2021.
(60) Provisional application No. 63/136,429, filed on Jan. 12, 2021.
(60) Provisional application No. 63/118,745, filed on Nov. 27, 2020.

(51) Int. Cl. H01L 27/146; H04N 25/709; H04N 25/78; H04N 25/20

(52) U.S. Cl. CPC H01L 27/1461; H01L 27/14649; H01L 27/1462; H04N 25/709; H04N 25/78; H04N 25/20

(57) ABSTRACT

Infrared (IR) photodetecting systems and methods. A system may comprise at least one photosite having a Ge photosensitive area (GPSA) that includes an absorber doped area having a first polarity and a Si layer comprising a first doped area (FDA), a storage well (SW), a floating diffusion (FD) and a transfer gate (TG); a controllable power source (CPS); and a controller, operable to control the CPS and the TG, to concurrently provide at a first time controlled voltages to the GPSA, FDA and FD, thereby forcing charge carriers of a given polarity (CCGP) from the GPSA toward the SW and to provide at another time other voltages to the GPSA, FDA and FD, thereby diminishing the forcing of the CCGP toward the SW and ceasing collection of signals by the SW, and to intermittently transfer the CCGP from the SW via the TG to the FD, where the CCSP are read via an electrode coupled to the FD.

### CROSS REFERENCE TO RELATED APPLICATIONS

This is a 371 application from international patent application PCT/IB2021/061033 filed Nov. 27, 2021, which claims priority from U.S. provisional patent applications No. 63/118,745 filed Nov. 27, 2020, No. 63/136,429, filed Jan. 12, 2021, and No. 63/194,977, filed May 29, 2021.

### FIELD

This disclosure is related to infrared (IR) focal plane arrays (FPAs), to methods for operation thereof, and especially to short wave IR (SWIR) FPAs which include germanium on silicon.

### BACKGROUND

Photodetecting devices such as photodetector arrays or “PDAs” (also referred to as “photosensor arrays”) include a multitude of photosites, each photosite including one or more photodiodes for detecting impinging light and capacitance for storing charge provided by the photodiode. Hereinbelow, “photosite” is often replaced with the acronym “PS”. The capacitance may be implemented as a dedicated capacitor and/or using parasitic capacitance of the photodiode, transistors, and/or other components of the PS. Henceforth in this description and for simplicity, the term “photodetecting device” is often replaced with the acronym “PDD”, the term “photodetector array” is often replaced with the acronym “PDA”, and the term “photodiode” is often replaced with the acronym “PD”.

The term “photosite” pertains to a single sensor element of an array of sensors (also referred to “sensel”, as in a portmanteau of the words “sensor” and “cell” or “sensor” and “element”), and is also referred to as “sensor element”, “photosensor element”, “photodetector element”, and so on. Each PS may include one or more PDs (e.g., if color filter array is implemented, PDs which detect light of different parts of the spectrum may optionally be collectively referred to as single PS). The PS may also include some circuitry or additional components in addition to the PD.

Dark current is a well-known phenomenon, and when referring to PDs it pertains to an electric current that flows through the PD even when no photons are entering the device. Dark current in PDs may result from random generation of electrons and holes within a depletion region of the PD.

In some cases, there is a need to provide PSs with photodiodes characterized by a relatively high dark current, while implementing capacitors of limited size. In some cases, there is a need to provide PSs with PDs characterized by a relatively high dark current while reducing effects of the dark current on an output detection signal. In PSs characterized by high dark current accumulation, there is a need for, and it would be advantageous to overcome detrimental effects of dark current on electrooptical systems. Henceforth and for simplicity, the term “electrooptical” may be replaced with the acronym “EO”.

Short-wave infrared (SWIR) imaging enables a range of applications that are difficult to perform using imaging of visible light. Applications include electronic board inspection, solar cell inspection, produce inspection, gated imaging, identifying and sorting, surveillance, anti-counterfeiting, process quality control, and much more. Many existing InGaAs-based SWIR imaging systems are expensive to fabricate, and currently suffer from limited manufacturing capacity.

It would therefore be advantageous to be able to provide SWIR imaging systems using more cost-effective photoreceivers based on PDs that are more easily integrated into the surrounding electronics.

Photodetector arrays which include a plurality of PSs, each being sensitive to a part of the electromagnetic spectrum are known in the art. However, these PDAs are either expensive, insensitive in ranges of interest of the electromagnetic spectrum, and/or inefficient in distance analysis. There is therefore a need in the art for improved PSs and PDAs. Further limitations and disadvantages of conventional, traditional, and proposed approaches will become apparent to one of skill in the art, through comparison of such approaches with the subject matter of the present application as set forth in the remainder of the present application with reference to the drawings.

### SUMMARY

In some aspects, there is disclosed an IR photodetecting system operable to detect IR radiation, comprising: (a) at least one PS that includes (i) a germanium (Ge) photosensitive area operable to generate electron-hole (e-h) pairs in response to impinging IR photons, the Ge photosensitive area including an absorber doped area having a first polarity, and (ii) a silicon (Si) layer including a diode, the diode including a first doped area of the first polarity and a second doped area of a second polarity opposite to the first polarity, wherein the first doped area is located between the second doped area and the absorber doped area; (b) at least one power source, operable to provide a first area voltage to the first doped area and to provide a second area voltage to the second area; and (c) a controllable power source, operable to (i) provide to the Ge photosensitive area, for a sampling duration of the PS an activation voltage which forces charge carriers of the second polarity (CCSP) to move from the Ge photosensitive area toward the photodiode where the CCSP are collected via a readout electrode electrically connected to the second doped area, and (ii) provide to the Ge photosensitive area, upon ending of the sampling duration, a rest voltage which diminishes the forcing of the CCSP toward the photodiode, thereby ceasing the collection of signals by the PS.

In some aspects, there is disclosed an electro-optical (EO) detection system, comprising: (a) an IR photodetecting system or sensor that includes a plurality of PSs; (b) at least one optical interface for directing light from a field of view (FOV) of the electro-optical detection system onto the IR photodetecting sensor; (c) readout circuitry operable to read from each of the plurality of PSs at least one electric signal corresponding to a number of photons captured by the Ge photosensitive area during the sampling duration of the respective PS; and (d) a processor operable to process the detection data provided by the readout circuitry, which is indicative of the plurality of electric signals, in order to provide an IR image of the FOV.

In some aspects, there is disclosed an IR photodetecting system operable to detect IR radiation, comprising: (a) at least one PS that includes: (i) a Ge photosensitive area operable to generate e-h pairs in response to impinging IR photons, the Ge photosensitive area including an absorber doped area having a first polarity, and (ii) a Si layer including a first doped area, a storage well, a floating diffusion, and a transfer gate; (b) at least one controllable power source operable to modulate voltage to at least one of the first doped area, the Ge photosensitive area and the floating diffusion; and (c) a controller operable to control the controllable power source and the transfer gate for, (i) at one time, to provide voltages to the Ge photosensitive area, to the first doped area, and to the floating diffusion, thereby forcing charge carriers of the second polarity to move from the Ge photosensitive area toward the storage well, (ii) at another time, provide other voltages to the Ge photosensitive area, to the first doped area, and to the floating diffusion, thereby diminishing the forcing of the charge carriers of the second polarity toward the storage well, thereby ceasing the collection of signals by the storage well, and (iii) intermittently transferring charge carriers of the second polarity from the storage well via the transfer gate to the floating diffusion, where they are read via a readout electrode electrically connected to the floating diffusion.

In some aspects, there is disclosed an IR photodetecting system operable to detect IR radiation, comprising: (a) at least one PS that includes: (i) a Ge photosensitive area, operable to generate e-h pairs in response to impinging IR photons, the Ge photosensitive area including an absorber doped area doped with a first polarity, and (ii) a silicon layer in which multiple readout structures are implemented, each readout structure including: (1) a remote doped area doped with a second polarity and (2) an intermediary doped area positioned between the remote doped area and the Ge photosensitive area, the intermediary doped area being doped with a second polarity opposite to the first polarity; (b) a controllable power source, operable to provide controlled voltages to the Ge photosensitive area, to the remote doped area and to the intermediary doped area of each of the multiple readout structures, the controllable power source being operable to: (i) maintain, for a first sampling duration, relative voltages on the Ge photosensitive area, a first remote doped area of a first readout structure out of the multiple readout structures, and a first intermediary doped area of the first readout structure, such that the CCSP are forced to move from the Ge photosensitive area toward the first readout structure by a first pulling force, where the CCSP are collected via a first readout electrode electrically connected to the first remote doped area, (ii) maintain, for the first sampling duration, voltages on the doped areas of a first group of readout structures that includes the rest of the multiple readout structures other than the first readout structure, such that a pulling force applied to the CCSP towards each of the remote doped areas of the first group of readout structures is less than half of the first pulling force, (iii) maintain, for a second sampling duration that is later than the first sampling duration, relative voltages on the Ge photosensitive area, a second remote doped area of a second readout structure out of the multiple readout structures, and a second intermediary doped area of the second readout structure, such that the CCSP are forced to move from the Ge photosensitive area toward the second readout structure by a second pulling force, where the CCSP are collected via a second readout electrode electrically connected to the second remote doped area; (iv) maintain, for the second sampling duration, voltages on the doped areas of a second group of readout structures that includes the rest of the multiple readout structures other than the second readout structure, such that a pulling force applied to the CCSP towards each of the remote doped areas of the second group of readout structures is less than half of the second pulling force; (v) maintain, for a third sampling duration that is later than the second sampling duration, relative voltages on the Ge photosensitive area, the first remote doped area, and the first intermediary doped area, such that CCSP are forced to move from the Ge photosensitive area toward the first readout structure by a third pulling force, where the CCSP are collected via the first readout electrode, and (vi) maintain, for the third sampling duration, voltages on the doped areas of the first group of readout structures, such that a pulling force applied to CCSP towards each of the remote doped areas of the first group of readout structures is less than half of the third pulling force.

In some aspects, there is disclosed a method for detecting IR radiation, comprising: (a) providing first area voltage to a first doped area of a PS and providing second area voltage to a second area of the PS which includes (i) a Ge photosensitive area operable to generate e-h pairs in response to impinging IR photons, the Ge photosensitive area including an absorber doped area having a first polarity, and (ii) a Si layer including a diode, the diode including the first doped area of the first polarity and the second doped area of a second polarity opposite to the first polarity; wherein the first doped area is located between the second doped area and the absorber doped area; (b) while providing the first area voltage and the second area voltage, providing to the Ge photosensitive area for a sampling duration of the PS an activation voltage which forces charge carriers of the second polarity to move from the Ge photosensitive area toward the photodiode where the CCSP are collected via a readout electrode electrically connected to the second doped area; and (c) upon ending of the sampling duration, providing to the Ge photosensitive area a rest voltage which diminishes the forcing of the CCSP toward the photodiode, thereby ceasing the collection of signals by the PS.

In some aspects, there is disclosed a method for detecting IR radiation, comprising: modulating voltage to at least one area of a PS (PS) selected from a group consisting of: a first doped area of the PS, a Ge photosensitive area of the PS and a floating diffusion of the PS, wherein the PS includes at least: (a) the Ge photosensitive area that is operable to generate e-h pairs in response to impinging IR photons and which includes an absorber doped area having a first polarity; and (b) a Si layer including the first doped area, a storage well, the floating diffusion, and a transfer gate. The modulating includes: (a) providing voltages to the Ge photosensitive area, to the first doped area, and to the floating diffusion, thereby forcing charge carriers of the second polarity to move from the Ge photosensitive area toward the storage well; (b) at another time, providing other voltages to the Ge photosensitive area, to the first doped area, and to the floating diffusion, thereby diminishing the forcing of the CCSP toward the storage well, thereby ceasing the collection of signals by the storage well; and (c) intermittently transferring charge carriers of the second polarity from the storage well via the transfer gate to the floating diffusion, where they are read via a readout electrode electrically connected to the floating diffusion.

In some aspects, there is disclosed a method for detecting IR radiation, comprising providing controlled voltages to areas of a PS that includes (i) a Ge photosensitive area that is operable to generate e-h pairs in response to impinging IR photons and which includes an absorber doped area doped with a first polarity, and (ii) doped areas of a multiple readout structures implemented on a Si layer of the PS, including, for each of the multiple readout structures, (a) a remote doped area doped with a second polarity and (b) an intermediary doped area positioned between the remote doped area and the Ge photosensitive area, the intermediary doped area being doped with a second polarity opposite to the first polarity. The providing may include: maintaining, for a first sampling duration, relative voltages on the Ge photosensitive area, a first remote doped area of a first readout structure out of the multiple readout structures, and a first intermediary doped area of the first readout structure, such that charge carriers of the second polarity are forced to move from the Ge photosensitive area toward the first readout structure by a first pulling force, where the CCSP are collected via a first readout electrode electrically connected to the first remote doped area; maintaining, for the first sampling duration, voltages on the doped areas of a first group of readout structures that includes the rest of the multiple readout structures other than the first readout structure, such that a pulling force applied to charge carriers of the second polarity towards each of the remote doped areas of the first group of readout structures is less than half of the first pulling force; maintaining, for a second sampling duration that is later than the first sampling duration, relative voltages on the Ge photosensitive area, a second remote doped area of a second readout structure out of the multiple readout structures, and a second intermediary doped area of the second readout structure, such that charge carriers of the second polarity are forced to move from the Ge photosensitive area toward the second readout structure by a second pulling force, where the CCSP are collected via a second readout electrode electrically connected to the second remote doped area; maintaining, for the second sampling duration, voltages on the doped areas of a second group of readout structures that includes the rest of the multiple readout structures other than the second readout structure, such that a pulling force applied to charge carriers of the second polarity towards each of the remote doped areas of the second group of readout structures is less than half of the second pulling force; maintaining, for a third sampling duration that is later than the second sampling duration, relative voltages on the Ge photosensitive area, the first remote doped area, and the first intermediary doped area, such that charge carriers of the second polarity are forced to move from the Ge photosensitive area toward the first readout structure by a third pulling force, where the CCSP are collected via the first readout electrode; and maintaining, for the third sampling duration, voltages on the doped areas of the first group of readout structures, such that a pulling force applied to charge carriers of the second polarity towards each of the remote doped areas of the first group of readout structures is less than half of the third pulling force.

In some aspects, there is disclosed a method for generating a depth image of a scene based on detections of a SWIR electrooptical imaging system (SEI system), comprising: obtaining a plurality of detection signals of the SEI system each detection signal indicative of amount of light captured by at least one focal plane array detector (FPA) of the SEI system from a specific direction within a FOV of the SEI system over a respective detection time frame, the at least one FPA including a plurality of individual PSs, each PS including a Ge element in which impinging photons are converted to detected electric charge, wherein for each direction out of a plurality of directions within a FOV, different detection signals are indicative of reflected SWIR illumination levels from different distances ranges along the direction; and processing the plurality of detection signals to determine a 3D detection map including a plurality of 3D locations in the FOV in which objects are detected; wherein the processing includes compensating for dark current (DC) levels accumulated during the collection of the plurality of detection signals resulting from the Ge elements; wherein the compensating includes applying different degrees of DC compensation for detection signals detected by different PSs of the at least one FPA.

In some aspects, there is disclosed a sensor operable to detect depth information of an object, comprising: a FPA including a plurality of PSs, each PS operable to detect light arriving from an instantaneous field of view (IFOV) of the PS, wherein different PSs are directed in different directions within a field of view of the sensor; a readout-set of readout circuitries, each being connected to a readout-group of PSs of the FPA by a plurality of switches, and operable to output an electric signal indicative of an amount of light impinging on the PSs of the readout-group when the readout group is connected to the respective readout circuitry via at least one of the plurality of switches; a controller operable to change switching states of the plurality of switches, such that different readout circuits of the readout-set are connected to the readout-group at different times, for exposing different readout circuits to reflections of illumination light from objects located at different distances from the sensor; and a processor, configured to obtain the electric signals from the readout-set indicative of detected levels of reflected light collected from the IFOVs of the readout-group of photosites for determining depth information for the object, indicative of a distance of the object from the sensor.

### BRIEF DESCRIPTION OF THE DRAWINGS

In order to understand the disclosure and to see how it may be carried out in practice, embodiments will now be described, by way of non-limiting examples only, with reference to the accompanying drawings, in which the following examples corresponding with different aspects of the presently disclosed subject matter are provided:

FIGS. 1A and 2A are cross section diagrams illustrating examples of photosites of IR photodetecting systems;

FIGS. 1B and 2B are diagrams illustrating diminished movement of charge carriers during a rest duration in the systems of FIGS. 1A and 2A, respectively;

FIGS. 3A and 3B are top view illustrations of two examples of photosites;

FIG. 4 illustrates voltages applied to photosite electrodes during consecutive sampling cycles;

FIG. 5 illustrates an IR photodetecting system;

FIG. 6 is a block diagram illustrating an electrooptical system which includes an IR photodetecting system;

FIG. 7 is a flow chart illustrating an example of a method for sensing light from a field of view;

FIG. 8 is a cross section diagram illustrating a photosite of an IR photodetecting system;

FIG. 9 illustrates states applied to a voltage modulation on one or more electrodes of a photosite and states applied to a transfer gate during consecutive sampling cycles;

FIG. 10 illustrates a photosite;

FIG. 11 illustrates a photosite,

FIG. 12A is a top view illustration of a photosite;

FIG. 12B is a top view illustration of an example of photosite;

FIGS. 13A, 13B, and 13C illustrate cross-section views and a top view of a photosite;

FIGS. 14A and 14B illustrate relative voltages which may be applied to different areas of a photosite during its operation;

FIG. 14C illustrates exemplary relationships between the voltages applied to the different electrodes at different operational states;

FIGS. 15, 16, 17, and 18 illustrate photodetector arrays having N-tap photosites;

FIG. 19 illustrates a method for detecting light arriving from a field-of-view of a photodetector array which includes a plurality of photosites;

FIGS. 20A and 20B are a cross section diagrams illustrating examples of photosites of IR photodetecting systems;

FIG. 21 illustrates a photosite;

FIGS. 22 and 23 illustrate methods for detecting IR radiation;

FIG. 24 illustrates a method for generating a depth image of a scene based on detections of a SWIR electrooptical imaging system;

FIG. 25 illustrates the timing of three different detection signals arriving from the same direction within the FOV;

FIGS. 26A-26C illustrate a sensor in different operational states;

FIG. 27 includes different timing diagrams;

FIGS. 28A-28C illustrate a sensor in different operational states;

FIG. 29 illustrate a sensor;

FIG. 30 illustrates a field of view of an electrooptical system, and a plurality of instantaneous FOVs;

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following detailed description, numerous specific details are set forth in order to provide a thorough understanding of the disclosure. However, it will be understood by those skilled in the art that the present disclosure may be practiced without these specific details. In other instances, well-known methods, procedures, and components have not been described in detail so as not to obscure the present disclosure.

In the drawings and descriptions set forth, identical reference numerals indicate those components that are common to different embodiments or configurations.

Unless specifically stated otherwise, as apparent from the following discussions, it is appreciated that throughout the specification discussions utilizing terms such as “processing”, “calculating”, “computing”, “determining”, “generating”, “setting”, “configuring”, “selecting”, “defining”, or the like, include action and/or processes of a computer that manipulate and/or transform data into other data, said data represented as physical quantities, e.g. such as electronic quantities, and/or said data representing the physical objects.

The terms “computer”, “processor”, and “controller” should be expansively construed to cover any kind of electronic device with data processing capabilities, including, by way of non-limiting example, a personal computer, a server, a computing system, a communication device, a processor (e.g. digital signal processor (DSP), a microcontroller, a field programmable gate array (FPGA), an application specific integrated circuit (ASIC), etc.), any other electronic computing device, and or any combination thereof.

The operations in accordance with the teachings herein may be performed by a computer specially constructed for the desired purposes or by a general-purpose computer specially configured for the desired purpose by a computer program stored in a computer readable storage medium.

As used herein, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure, or characteristic described in connection with the embodiment(s) is included in at least one embodiment of the presently disclosed subject matter. Thus, the appearance of the phrase “one case”, “some cases”, “other cases” or variants thereof does not necessarily refer to the same embodiment(s).

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination.

In embodiments of the presently disclosed subject matter one or more stages illustrated in the figures may be executed in a different order and/or one or more groups of stages may be executed simultaneously and vice versa. The figures illustrate a general schematic of the system architecture in accordance with an embodiment of the presently disclosed subject matter. Each module in the figures can be made up of any combination of software, hardware and/or firmware that performs the functions as defined and explained herein. The modules in the figures may be centralized in one location or dispersed over more than one location.

Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that may be executed by the system and should be applied mutatis mutandis to a non-transitory computer readable medium that stores instructions that may be executed by the system.

Any reference in the specification to a non-transitory computer readable medium should be applied mutatis mutandis to a system capable of executing the instructions stored in the non-transitory computer readable medium and should be applied mutatis mutandis to method that may be executed by a computer that reads the instructions stored in the non-transitory computer readable medium.

In order to understand the disclosure and to see how it may be carried out in practice, embodiments will now be described, by way of non-limiting examples only, with reference to the accompanying drawings. It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

In the following detailed description, numerous specific details are set forth in order to provide a thorough understanding of the disclosure. However, it will be understood by those skilled in the art that the present disclosure may be practiced without these specific details. In other instances, well-known methods, procedures, and components have not been described in detail so as not to obscure the present disclosure.

In the drawings and descriptions set forth, identical reference numerals indicate those components that are common to different embodiments or configurations.

Unless specifically stated otherwise, as apparent from the following discussions, it is appreciated that throughout the specification discussions utilizing terms such as “processing”, “calculating”, “computing”, “determining”, “generating”, “setting”, “configuring”, “selecting”, “defining”, or the like, include action and/or processes of a computer that manipulate and/or transform data into other data, said data represented as physical quantities, e.g. such as electronic quantities, and/or said data representing the physical objects.

The terms “computer”, “processor”, and “controller” should be expansively construed to cover any kind of electronic device with data processing capabilities, including, by way of non-limiting example, a personal computer, a server, a computing system, a communication device, a processor (e.g. digital signal processor (DSP), a microcontroller, a field programmable gate array (FPGA), an application specific integrated circuit (ASIC), etc.), any other electronic computing device, and or any combination thereof.

The operations in accordance with the teachings herein may be performed by a computer specially constructed for the desired purposes or by a general-purpose computer specially configured for the desired purpose by a computer program stored in a computer readable storage medium.

As used herein, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure, or characteristic described in connection with the embodiment(s) is included in at least one embodiment of the presently disclosed subject matter. Thus, the appearance of the phrase “one case”, “some cases”, “other cases” or variants thereof does not necessarily refer to the same embodiment(s).

It is appreciated that certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination.

In embodiments of the presently disclosed subject matter one or more stages illustrated in the figures may be executed in a different order and/or one or more groups of stages may be executed simultaneously and vice versa. The figures illustrate a general schematic of the system architecture in accordance with an embodiment of the presently disclosed subject matter. Each module in the figures can be made up of any combination of software, hardware and/or firmware that performs the functions as defined and explained herein. The modules in the figures may be centralized in one location or dispersed over more than one location.

Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that may be executed by the system and should be applied mutatis mutandis to a non-transitory computer readable medium that stores instructions that may be executed by the system.

Any reference in the specification to a non-transitory computer readable medium should be applied mutatis mutandis to a system capable of executing the instructions stored in the non-transitory computer readable medium and should be applied mutatis mutandis to method that may be executed by a computer that reads the instructions stored in the non-transitory computer readable medium.

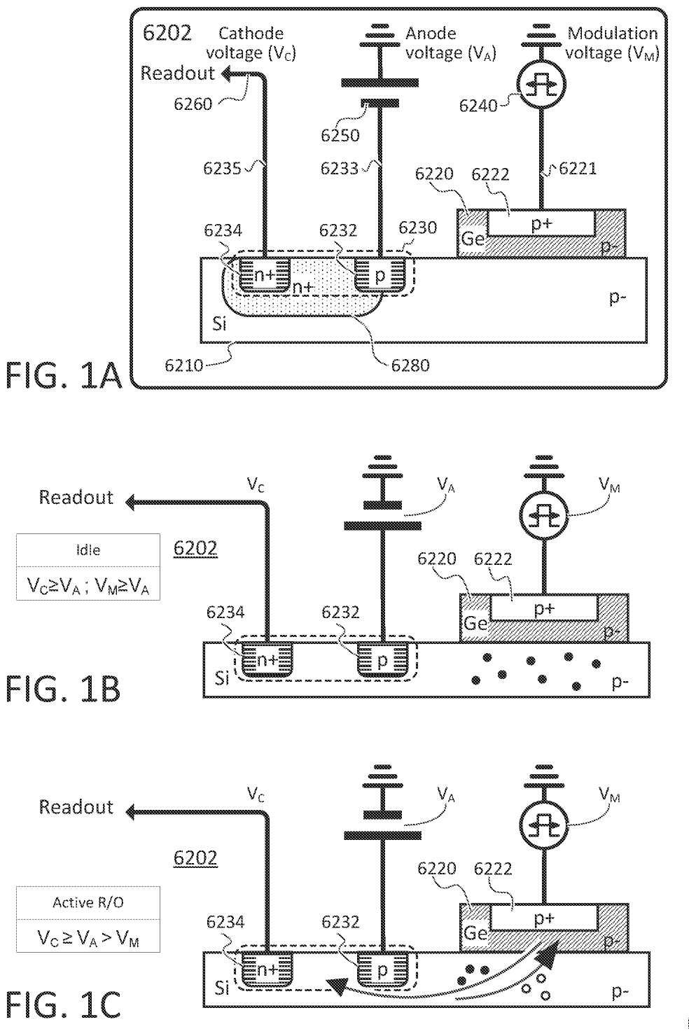

FIG. 1A is a cross section diagram illustrating an example of a photosite 6202 of an IR photodetecting system 6200, in accordance with examples of the presently disclosed subject matter. IR photodetecting system 6200 (also referred to below as “IR system 6200” or just “system 6200”) is sensitive to photons in the IR region. While not necessarily so, IR photodetecting system 6200 may be an IR photodetecting sensor or include an IR photodetecting sensor. While not necessarily so, IR photodetecting system 6200 may be a SWIR photodetecting sensor or include a SWIR photodetecting sensor. Referring to the photodetecting sensors discussed and claimed below it is noted that the term “short-wave infrared sensor” and similar terms (e.g., “short-wave infrared FPA sensor”, “short-wave infrared FPA”) pertain to photosensitive sensors which can absorb and detect impinging short-wave infrared radiation (i.e., radiation whose wavelength is between 1,000 and 1,700 nm). It is noted that such sensors may also be sensitive to other parts of the spectrum (e.g., shorter than 1,000 nm) in addition to being sensitive to parts of the SWIR spectrum. Especially, such photodetecting sensors may optionally be sensitive to parts of the visible spectrum (between 400 and 700 nm), but this is not necessarily so. In at least part of the SWIR spectrum, the quantum efficiency of these SWIR sensors is higher than is achievable by Si based photosensors (which are more suitable to sensing within the visible spectrum). Optionally, the disclosed and claimed SWIR systems may be sensitive to impinging illumination within subsections of the short-wave IR spectrum (which, for the purposes of the present disclosure, is defined to be between 1,000 nm and 1,700 nm), and even more specifically between 1,200 nm and 1,550 nm. A sensor is defined to be sensitive for a given wavelength within the context of the present disclosure if a quantum efficiency of the sensor for that wavelength is higher than 5%.

IR system 6200 may include one or more photosites (PSs) 6202. For example, IR system 6200 may include hundreds, thousands, tens of thousands, hundreds of thousands, millions or more PSs 6202, whose detection signals may be processed to generate an image, a video, or a 3D model of a objects in a FOV of IR system 6200 (or of an electrooptical system in which IR system 6200 is integrated). For example, IR system 6200 may include 1280×720 PSs 6202, for generating a HD-resolution image. In other examples, IR system 6200 may include 640×480, 1440×900, or 1920×1080 PSs 6202, or any other deployment of PSs (whether standard or nonstandard, rectangularly tiled, hexagonally tiled (also referred to as “honeycomb tiled”), or any other geometrical arrangement of PS s). Any of the PS arrays discussed throughout the present disclosure may be used as imaging receivers.

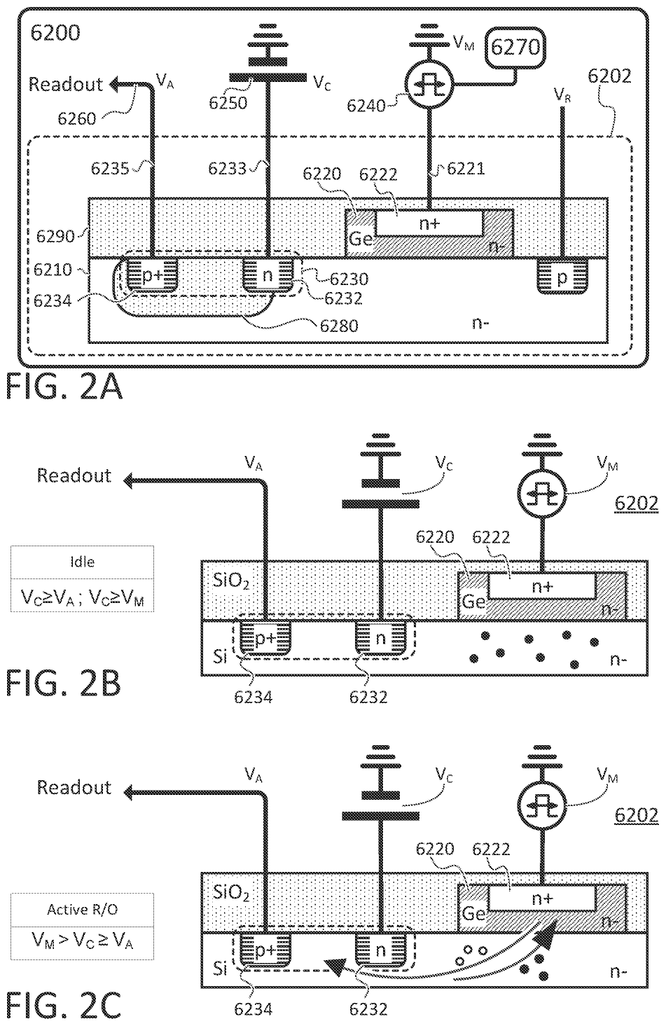

PS 6202 includes Si layer 6210 in which diode 6230 is implemented. Diode 6230 includes two doped areas: first doped area 6232 and second doped area 6234. First doped area 6232 has a first polarity (positive in the example of FIG. 1A, negative in the example of FIG. 2A), and second doped area has a second polarity which is the opposite polarity to the first polarity (the second polarity is negative in the example of FIG. 1A, and positive in the example of FIG. 2A). Optionally, Si layer 6210 is a Silicon-On-Insulator (SOI) layer.

In addition to the Si layer, PS 6202 further includes a Ge photosensitive area (or simply “Ge area”) 6220, which is operable to generate e-h pairs in response to impinging IR photons (and possibly also to photons in other parts of the electromagnetic spectrum, such as the near IR (NIR) and the visible (VIS) parts of the spectrum. The term “Ge area” pertains to a bulk of material in which light-induced excitation of electrons occurs within the Ge, within a Ge alloy (e.g., SiGe), or on the border of Ge (or Ge alloy) and another material (e.g., Si, SiGe). Specifically, the term “Ge area” pertains both to pure Ge bulks and to Ge—Si bulks. When Ge bulks which include both Ge and Si are used, different concentration of Ge may be used. For example, the relative portion of Ge in the Ge area (whether alloyed with Si or adjacent to it) may range from 5% to 99%. For example, the relative portion of Ge in the Ge area may be between 15% and 40%. It is noted that materials other than Si such as aluminum, nickel, silicide, or any other suitable material may also be part of the Ge area. In some implementations, the Ge area may be a pure Ge area (including more than 99.0% Ge). Ge area 6220 can be deposited on Si layer 6210 in any suitable way, such as—but not limited to—epi growth of uniform layer, selective layer epitaxy method, and so on.

Within Ge area 6220 there is at least one doped area 6222 (also referred to as “absorber doped area”) with the first polarity (i.e., the same polarity of first area 6232; positive in the example of FIG. 1A, negative in the example of FIG. 2A). Referring to the doping levels of the different parts of PS 6202, it is noted that the relative doping ratios illustrated are exemplary, and that different relative doping levels (e.g., “−”, “+”, “++”) are offered by way of example only, and that any suitable combination of relative doping levels and polarities may be used.

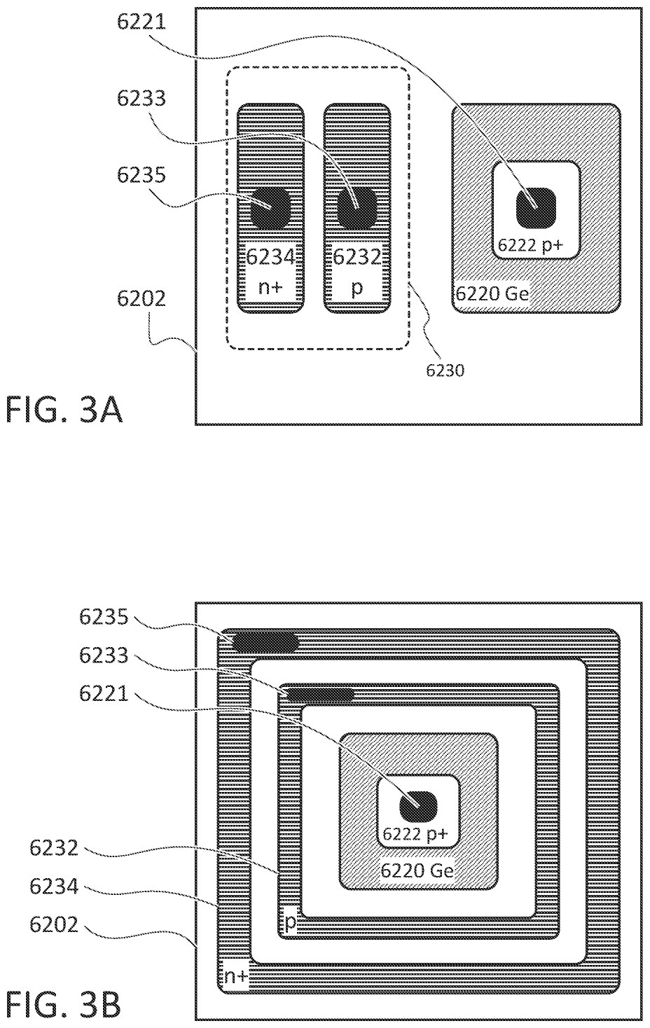

Geometrically, first doped area 6232 is located between the second doped area and the absorber doped area. This means, in the context of the present disclosure, that most (or all of) the straight lines between points on the Ge area 6220 and points on the second doped area 6234 (of the opposing electric polarity) pass though, below, or above at least one point of the first doped area 6232. This way, controlling the relative voltages in the Ge area 6220, the first doped area 6232 and the second doped area 6234 affects movement of charge carriers generated in the Ge area 6220 to the readout of the respective PS 6202, as discussed below. FIGS. 3A and 3B are top view illustrations of two examples of PS 6202 (showing only some of the components, for reasons of clarity). Voltages applied to the different doped areas are transmitted via three electrodes (or combinations of electrodes). One or more electrodes 6221 provide voltage to Ge area 6220 (optionally specifically to doped area 6222 with Ge area 6220). This voltage is referred to in the diagrams as “modulation voltage” and as “V_{M}”. One or more electrodes 6233 provide voltage to first doped area 6232, and one or more electrodes 6235 provide voltage to second doped area 6234. The voltage which is provided to the positively doped area (out of areas 6232 and 6234) is referred to in the diagrams as “Anode voltage” and as “V_{A}”, while the voltage provided to the negatively doped area (out of areas 6232 and 6234) is referred to in the diagrams as “Cathode voltage” and as “V_{C}”. Voltage is provided by one or more power sources. Such a power source may be constant (routinely providing a single constant voltage when on), modulated (e.g., providing a modulated voltage between discrete voltages, or gradually modifying provided voltage), or any other type of power source. In the illustrated example, only the voltage provided to the Ge area 6220 is modulated, but as discussed below, modulation of the other voltages (denoted V_{A} and V_{C}) may also be implemented.

IR system 6200 includes at least one power source (e.g., power source 6250 and/or a power source connected to electrode 6235) that is operable to provide first-area voltage to first doped area 6232 and to provide second-area voltage to second area 6234. These voltages are used for biasing diode 6230. Optionally, the biasing may be constant in time. However, this is not necessarily so. In the illustrated examples, the biasing is always active (both V_{A} and V_{C} are set to their high level both during the active readout phase and the idle rest time of the respective PS 6202), but in in some implementations, the biasing voltages are not necessarily active at all times.

IR system 6200 also includes at least one controllable power source 6240 which is operable to:
a. provide to Ge area 6222—for a sampling duration of the PS 6202—an activation voltage which forces charge carriers of the second polarity to move from Ge area 6222 (where charge carriers are generated as result of impinging light) toward diode 6230, where the CCSP are collected via a readout electrode 6235 which is electrically coupled to second doped area 6234. In the example of FIGS. 1A-1C the CCSP are electrons, while in the example of FIGS. 2A-2C the CCSP are holes. Movement of charge carriers during the sampling duration is exemplified in FIGS. 1C and 2C. A connection to the readout circuit is denoted 6260 in the diagram.
b. provide to Ge area 6222—upon ending of the sampling duration, a rest voltage which diminishes (possibly outright ceasing) the forcing of the CCSP toward diode 6230, thereby ceasing the collection of signals by the respective PS 6202. The diminished movement of charge carriers during the rest duration is exemplified in FIGS. 1B and 2B.

Referring to the activation period, charge carriers of the second polarity are repelled by the voltage applied to Ge area 6220 and are attracted to the voltage applied to first doped area 6232. These charge carriers move past first doped area 6232 toward second doped area 6234 using a drift velocity resulting from the applied voltage between first doped area 6232 and second doped area 6234, e.g., in depletion region 6280 (which is identified only in FIGS. 1A and 2A, in order not to reduce the visual load of other diagrams).

IR system 6200 may optionally include controller 6270 (which may be implemented on the same chip as the PSs 6202, or be part of a larger electrooptical system of which the chip is a part). Optional controller may control the provision of the modulated voltage (or voltages) to the relevant PS electrodes, and may control other parts of the operation of IR system 6200 as well.

A sampling cycle of the PS 6202 includes two phases—a sampling duration during which signal is collected (and later sampled and optionally provided to external modules), and a rest duration during which signal is not collected. The ceasing of the applying of the activation voltage diminishes movement of charge carriers of the second polarity to the readout electrode 6235. Optionally, the sampling cycle of the PS 6202 includes just those two phases, and not any other phases. The movement during the rest duration is diminished, and not intentionally directed to another useful location on the PS. Especially, in some or all implementations, PS 6202 does not include other readout electrodes which are used for collection signal during the rest period. Optionally, the diminishing of the charges results from low lifetime expected for the charge carriers in Ge area 6220.

In case the first polarity is positive polarity, the combination of voltages (V_{A}, V_{C}, V_{M}) during the sampling duration may be one which fulfils the following condition: V_{C}≥V_{A}>V_{M}, and the combination of voltages when the sampling duration concludes (e.g., during the idle duration) fulfils at least the condition that; V_{M}≥V_{A}, and optionally also that V_{C}≥V_{A}

Inducing charge carriers of the second polarity toward the readout electrode in only part of the time may be used for selectively collecting electric signal during times for relatively short spans of times (e.g., corresponding to illumination by a light source). This may be useful, for example, to prevent dark current charge generated in the Ge area 6220 (which may be relatively very high in comparison to the dark current in Si photodetectors) from saturating the capacitance of the detectors. IR system 6200 implements the switching between sampling time and idle time in the semiconductor level, in comparison with readout—circuit electronic switching which is implemented using transistors or other electric components. Implementing the switching in the semiconductor level is characterized by significantly lower noise when compared to the noise introduced by switching in the readout circuitry level (e.g., thermal noise, also referred to as Johnson-Nyquist noise or kTC noise). It is nevertheless noted that the switching in the semiconductor level as discussed above may be combined with other forms of switching, even ones which are implemented in the readout circuitry.

It is noted that any voltage out of the activation voltage and/or the rest voltage may be a single voltage or a range of voltage. The any voltage out of the voltages applied to first doped area 6232 and to second doped area 6234 may also be a single voltage or a range of voltage. For example, the activation voltage may be 1V, 2V, or varying voltage within the range 1-2V. Likewise, the rest voltage may be 0.0V, −0.2V, 0.3V, or varying voltage within the range −0.2-0.3V. Optionally, an amplitude of the rest voltage is lower by at least 0.2V than an amplitude of the activation voltage. Optionally, the rest voltage may be zero or close to zero, but this is not necessarily so.

Referring to the power sources which provide voltage to electrodes 6221, 6233, and 6235, each of these power sources (modulated or constant) may provide voltage to one or more PSs 6202. The power sources (e.g., 6240, 6250) may be included within individual PSs 6202 (as exemplified in FIG. 1A) or externally to individual PSs 6202 (as exemplified in FIG. 2A). It is noted that the location of the power source with relation to the individual PS s 6202 is not related to the polarity of the different doped areas exemplified in the specific illustrations.

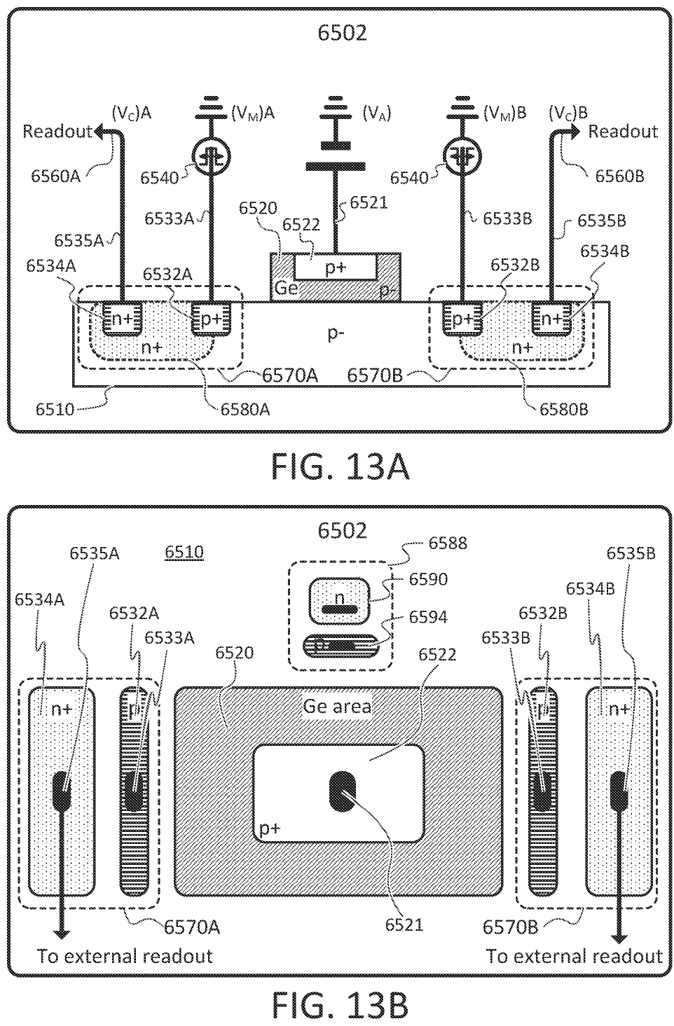

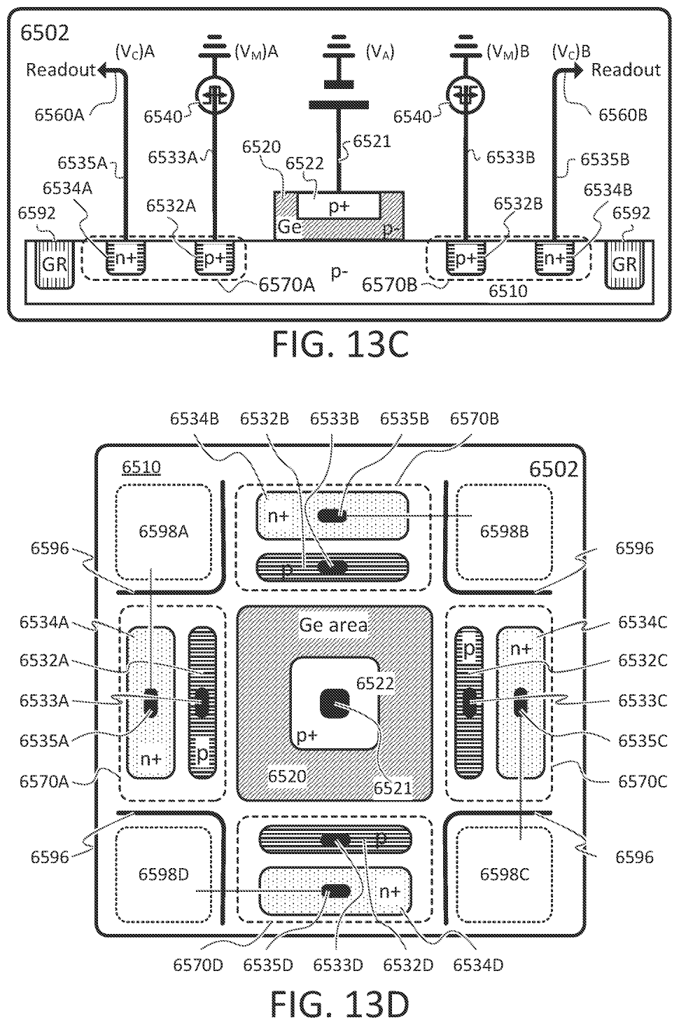

In the illustrated examples, the modulation is performed only on electrode 6221 which provides voltage to Ge area 6220. However, it will be clear to a person who is of skill in the art that equivalent implementations in which modulations on the anode voltage and/or the cathode voltage may also be used to generate movement of charge carriers of the second polarity from Ge area 6220 to second doped area 6234 during an activation duration of the PS 6202, and diminishing of that movement during a resting duration of the PS 6202. Modulations of V_{A} and/or V_{C} may be implemented together with modulation of V_{M}, but optionally the voltage to Ge area 6220 may be maintained constant in case V_{A} and/or V_{C} are modulated. An example of such an implementation is provided below with respect to PS 6502 of FIG. 13A, with respect to one side of the PS, and may be implemented in PS 6202 (or any other PS discussed below) mutatis mutandis.

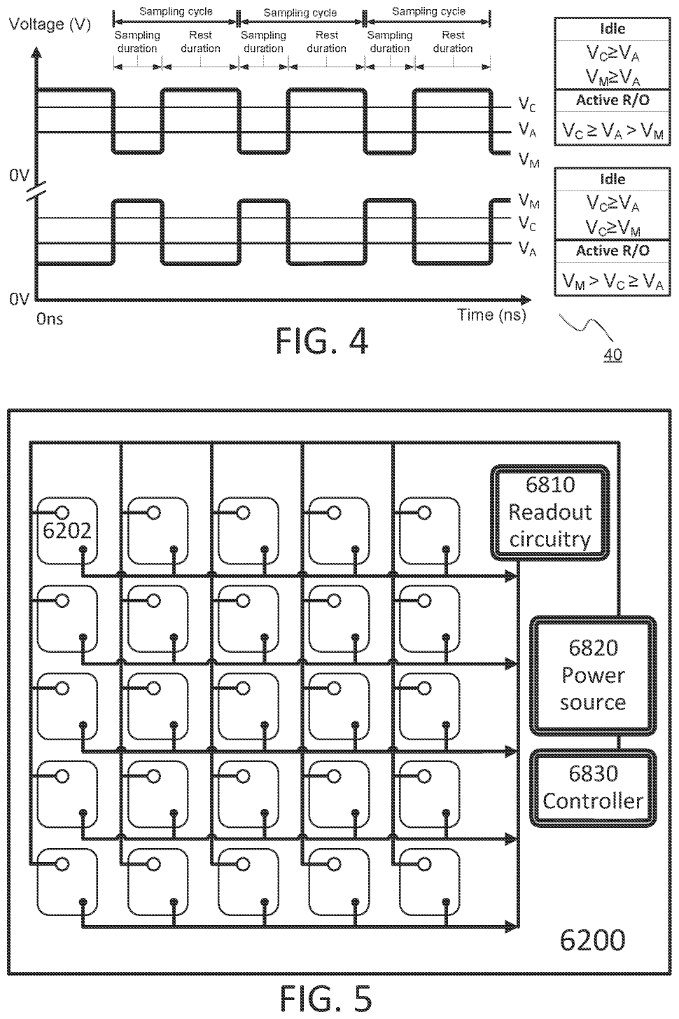

FIG. 4 includes voltages diagram 40, which illustrates voltages applied to electrodes 6221, 6233, and 6235 during consecutive sampling cycles, in accordance with examples of the presently disclosed subject matter. The top graph pertains to the example in which the first polarity is positive (e.g., as shown in FIGS. 1A-1C), and the bottom graph pertains to the example in which the first polarity is negative (e.g., as shown in FIGS. 2A-2C). The sampling cycles may be of the same duration, e.g., as exemplified in FIG. 4, but this is not necessarily so. The sampling durations of the different sampling cycles may be constant, e.g., as exemplified in FIG. 4, but this is not necessarily so. The rest durations of the different sampling cycles may be constant, e.g., as exemplified in FIG. 4, but this is not necessarily so.

The duration of the sampling cycles may optionally be determined with respect to a frame rate of the IR system 6200. For example, for a 60 fps frame rate, the duration of the sampling cycles may be 1/60 seconds each. If each frame of the 60 fps example require multiple exposure, the sampling cycles may be much shorter, and not necessarily of equal lengths. The sampling cycles may optionally be synchronized with illumination by an associated illumination source (if any). For example, IR system 6200 may be combined with at least one illumination source (e.g., laser, light emitting diode—LED) in a single electrooptical system (e.g., camera, LIDAR, spectrograph), and the sampling duration may start upon emission of light by the at least one light source. Each sampling duration may be associated with a single illumination span, with a plurality of illumination spans (e.g., in some pulsed illumination implementation), and may also be unsynchronized with illumination (e.g., if no illumination or if constant illumination is implemented). The sampling durations and/or the sampling cycles of different PS s 6202 may be synchronized (e.g., starting at the same time), cascaded (e.g., different rows of PS s in a photodetecting array may be triggered one after the other), or otherwise modulated.

The sampling duration may change in different embodiments of the disclosure. Optionally, one or more of the at least one sampling duration of PS 6202 is shorter than 10 nanoseconds. Optionally, one or more of the at least one sampling duration of PS 6202 is between 10-100 nanoseconds. Optionally, one or more of the at least one sampling duration of PS 6202 is between 100-500 nanoseconds. Optionally, one or more of the at least one sampling duration of PS 6202 is between 0.5-5 microseconds. Optionally, one or more of the at least one sampling duration of PS 6202 is longer than 5 microseconds.

While not necessarily so, Si layer 6210 and Ge area 6220 may optionally be doped with the first polarity. This may be used for creating a positive channel (or a negative channel).

Optionally, IR photodetecting system 6200 may include a spectral filter for blocking photons of the visible spectrum from reaching the photodiode. Spectral filters which block other parts of the electromagnetic spectrum (e.g., far IR parts of the spectrum, ultraviolet parts of the spectrum) may also be implemented. Blocking of photons of selected parts of the spectrum from reaching the diode may be implemented in order to prevent accumulation of signal which result from these photons (in the Ge area 6220 and/or in Si layer 6210). Optionally, one or more spectral filters may be implemented on the system level, in an electrooptical system in which IR system 6200 is integrated. For example, a window, a lens, a mirror, a prism, or another optical component which deflects light that is to be sensed by the system may be coated with a spectral filtering coating, or a dedicated spectral filter may be positioned on the incoming optical part. A spectral filter, if implemented, may be implemented on the same chip on which IR system 6200 is implemented, or in any other part of the electrooptical system (not illustrated).

Optionally, IR photodetecting system 6200 (or an electrical system in which the IR sensing chip is integrated) may include a cooling module (e.g., heat transfer fluid, heat sink, cold plate, Peltier cooling plate) for reducing heat caused by charge carrier of the first polarity collected via an electrode electrically coupled to Ge area 6220. It is noted that the current resulting from these charge carriers of the first polarity may be larger than the detection signal collected by the readout circuit. An intrinsic doping of Si layer 6210 and/or of Ge area 6220 may be such that reduce movement of charge carriers of the first polarity, thereby reducing a modulation current of charge carriers of the first polarity. This reduction of the modulation current of the charge carriers of the first polarity (by selecting a suitable doping level, e.g., a low level of doping) facilitates reduce thermal effects of the modulation current, thus reducing power consumption and alleviating (or reducing) the need for costly cooling mechanisms.

Optionally, IR photons from a FOV of the IR photodetecting system 6200 pass through the Si layer 6210 before being absorbed in Ge area 6220 (where they may cause generation of an e-h pair, depending on the quantum efficiency of the detector).

Optionally, IR photodetecting system 6200 may include a passivation layer 6290 between (a) the Ge area 6220 and diode 6230 on one side, and (b) the at least one power source (e.g., 6240, 6250) on the other side. Such passivation layer may be made from SiO₂, Si₃N₄, or any other suitable material. Optionally, IR photodetecting system 6200 may include a planarization layer (e.g., between (a) the Ge area 6220 and diode 6230 on one side, and (b) the at least one power source on the other side). Such planarization layer may be made from SiO₂, Si₃N₄, or any other suitable material. Optional passivation layer 6290 is illustrated in only FIGS. 2A-2C, but it is noted that it is not related to any specific polarity of the parts of IR system 6200.

Optionally, Ge area 6220 may be is overlayed on top of the Si layer (directly or indirectly on top of it). In other implementations (not shown), at least a part of the Ge area is sunk within the Si layer (e.g., within etched holes) and/or within the passivation layer (if any).

Optionally, IR photodetecting system 6200 may include at least one photo-effective layer bonded to a polished side of the Si layer positioned opposite to a side of the Si layer on which the Ge area is deployed. A photo-effective layer within the context of the present disclosure is a layer which manipulates the illumination passing through it. For example, the photo effective layer may operate as a chromatic filter, as a polarization filter, as any other type of optical filter, as a retarder, a diffraction grating, or any other type of layer which affect the light radiation which traverse the layer.

FIG. 5 illustrates IR photodetecting system 6200, in accordance with examples of the previously disclosed subject matter. In the illustrated example, the PSs 6202 are arranged in a rectangular matrix, and the power sources provide voltages to all of the PSs 6202 together. In order to keep the drawing simple and readable, all of the electrodes to the different parts of each PS 6202 are represented by a single line. Optionally, IR photodetecting system 6200 may include one or more readout circuitry 6810, implemented on the same wafer as one or more of PSs 6202, operable to read from each of the plurality of PSs at least one electric signal corresponding to a number of photons captured by the Ge area during the sampling duration of the respective PS. Optionally, IR photodetecting system 6200 may include one or more power sources 6820 which provide voltage for the operation of PSs 6202 (and possibly to additional components of IR photodetecting system 6200). Power source 6820 may provide power based on the instructions of controller 6830, which may also be implemented on the same wafer (but not necessarily so). In addition, optional controller 6830 may control operations of other parts of IR photodetecting system 6200, such as switching modules and so on.

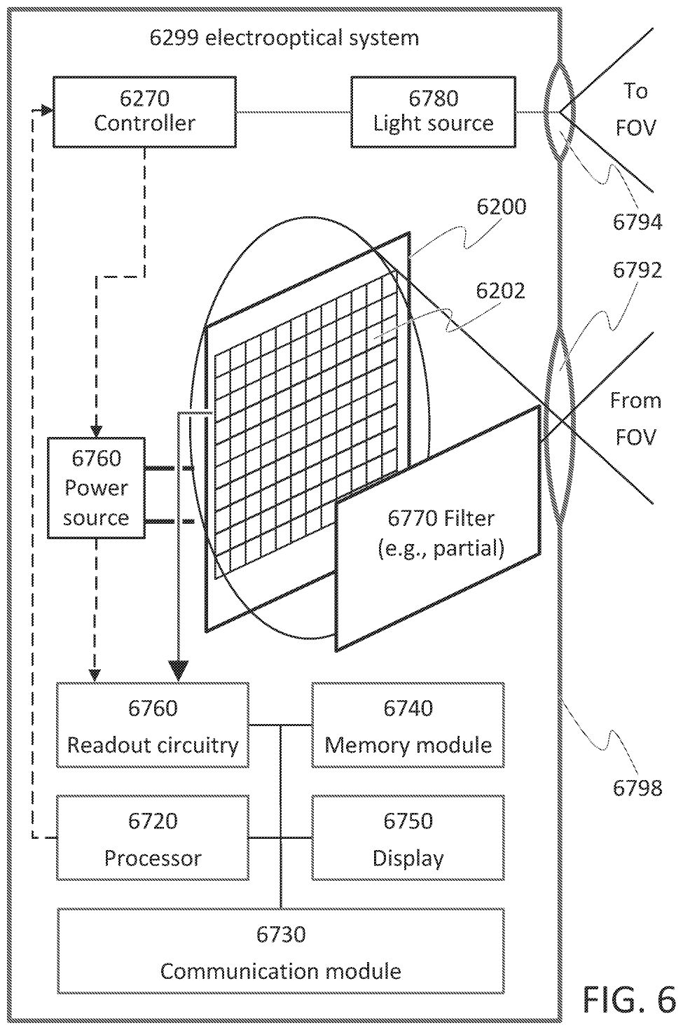

FIG. 6 is a block diagram illustrating an electrooptical system 6299 which includes IR photodetecting system 6200, in accordance with examples of the presently disclosed subject matter. FIG. 6 illustrates some of the components which may be included in such an electrooptical system, but it will be clear to a person who is of skill in the art that many other components may be implemented in an operational electrooptical system 6299. Examples for electrooptical system 6299 which may include system 6200 are: IR camera, Lidar, spectrograph, and so on.

Optionally, electro-optical detection system 6299 may include various additional components, many of which are known in the art, such as (but not limited to) any combination of one or more of the following components:
a. Any variation of IR photodetecting system 6200 (which includes a plurality of PSs);
b. At least one optical interface 6792 for directing light from a FOV of electro-optical detection system 6299 onto IR photodetecting sensor 6200. While optical interface 6792 is represented graphically as a single lens, it will be clear to a person who is of skill in the art that any suitable combination of optical components may be used, such as (but not limited to): lenses, mirrors, prisms, fiber optics, filters, beam splitters, retarders, and so on. Such optical components may be fixed or movable (especially in a controllable fashion);
c. At least one readout circuitry 6710 operable to read from each of the plurality of PSs at least one electric signal corresponding to a number of photons captured by the Ge area during the sampling duration of the respective PS. Readout circuitry 6710 may be used, for example, to read the detection signals from PSs 6202 and to provide the signals for further processing (e.g., in order to reduce noise, for image processing), for storage, or for any other use. For example, readout circuitry 6710 may temporally arrange the readout values of the different PS s 6202 sequentially (possibly after some processing) before providing them for further processing, storage, or any other action. Optionally, readout circuitry 6710 may be implemented as one or more units fabricated on the same wafer as other components of IR photodetecting system 6200 (e.g., PSs 6202, amplifiers). Optionally, readout circuitry 6710 may be implemented as one or more units on a printed circuit board (PCB) connected to such a wafer. Any other suitable type of readout circuitries may also be implemented as readout circuitry 6710. Examples for analog signal processing that may be executed in the electro-optical detection system 6299 (e.g., by readout circuitry 6710 or by one or more processors 6720 of the respective electro-optical detection system 6299) prior to an optional digitization of the signal include: modifying gain (amplification), offset and binning (combining output signals from two or more PSs). Digitization of the readout data may be implemented by electro-optical detection system 6299 or external thereto. Optionally, readout circuitry 6710 may include (or even consist of) the aforementioned readout circuitry 6810, but this is not necessarily so.
d. At least one processor 6720, operable to process the detection data provided by readout circuitry 6710, that is indicative of the plurality of electric signals, in order to provide an IR image of the FOV. It is noted that as readout circuitry 6710 is optional, any suitable way in which information indicative of signal levels of different PSs is provided to processor 6720 may be utilized. A processing by processor 6720 may include, for example, signal processing, image processing, spectroscopy analysis, and so on. Optionally, processing results by processor 6720 may be used for modifying operation of controller 6270 (or another controller). Optionally, controller 6270 and processor 6720 may be implemented as a single processing unit. Optionally, processing results by processor 6720 may be provided to any one or more of: a tangible memory module 6740 (e.g., for storage or later retrieval, see next), for external systems (e.g., a remote server, or a vehicle computer of a vehicle in which system 6299 is installed), e.g., via a communication module 6730, a display 6750 for displaying an image or another type of result (e.g., graph, textual results of spectrograph), another type of output interface (e.g. a speaker, not shown), and so on. It is noted that optionally, signals from PSs may also be processed by processor 6720, for example to assess a condition of IR system 6200 (e.g., operability, temperature).
e. At least one light source 6780, operable to emit light onto the FOV of electrooptical system 6299. Some of the light of light source 6780 is reflected from objects in the FOV and is captured by PSs 6202. This light may be used to generate an image or another model of the objects (e.g., by processor 6720). Any suitable type of light source may be used (e.g., pulsed, continuous, modulated, LED, laser). Optionally, operation of light source 6780 may be controlled by a controller (e.g., controller 6270).
f. At least one optical interface 6794 for directing light of one or more light source 6780 towards parts or the entirety of the FOV of electro-optical detection system 6299. While optical interface 6794 is represented graphically as a single lens, it will be clear to a person who is of skill in the art that any suitable combination of optical components may be used, such as (but not limited to): lenses, mirrors, prisms, fiber optics, filters, beam splitters, retarders, and so on. Such optical components may be fixed or movable (especially in a controllable fashion);
g. At least one filter 6770 for manipulating light collected from parts or the entirety of the FOV before it reaches the PSs 6202. Such a filter may include a physical barrier, a spectral filter, a polarizer, a retarder, or any other suitable type of filter. Filter 6770 may be part of the detector array (e.g., implemented as one or more layers on the same wafer) or external thereto. Filter 6770, if implemented, may be fixed or changeable (e.g., a moving shutter). Optionally, operation of filter 6770. if changeable, may be controlled by a controller (e.g., controller 6270).
h. At least one controller 6270, for controlling the operation of any one or more of the other components of electrooptical system 6299 (e.g., photodetector, light source, readout circuitry), either synchronously or otherwise. It is noted that any functionality of controller 6270 may be implemented by an external controller (e.g., implemented on another processor of electrooptical system 6270 which is not directly connected to the photodetector, or by an auxiliary system such as a controller of an autonomous vehicle in which the electrooptical system 6299 is installed). Optionally, controller 6270 may be implemented as one or more processors fabricated on the same wafer as other components of IR system 6200 (e.g., PSs 6202). Optionally, controller 6270 may be implemented as one or more processors on a printed circuit board (PCB) connected to such a wafer. Other suitable controllers may also be implemented as controller 6270. Optionally, controller 6270 may include (or even consist of) the aforementioned controller 6830, but this is not necessarily so.
i. At least one memory module 6740 for storing at least one of detection signals output by the PSs and/or by readout circuitry 6710 (e.g., if different), and detection information generated by processor 6720 by processing the detection signals.
j. At least one power source 6760 (e.g., battery, AC power adapter, DC power adapter). The power source may provide power to the PSs, to the amplifier, or to any other component of the photodetecting device.
k. A hard casing 6798 (or any other type of structural support).

Optionally, the processor of electrooptical system 6299 may be further configured to process the detection data in order to determine a presence of at least one object in the FOV.

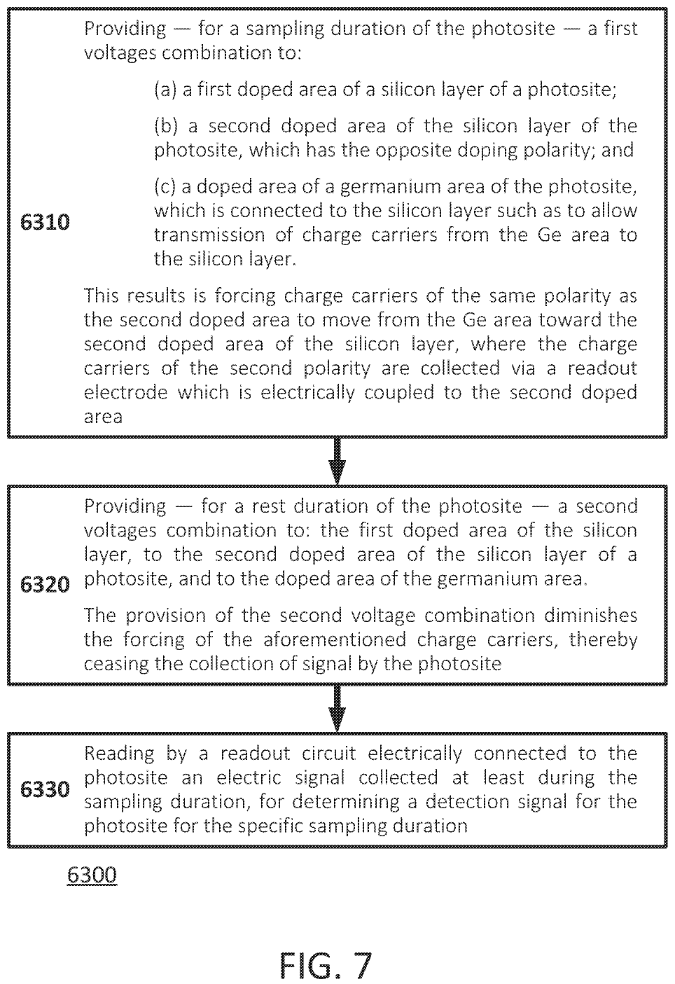

FIG. 7 is a flow chart illustrating an example of method 6300, in accordance with the presently disclosed subject matter. Method 6300 is a method for sensing light from a FOV. Referring to the examples of the accompanying drawings, method 6300 may optionally be carried out by IR system 6200, or by electrooptical system 6299.

Stage 6310 includes providing a first voltages combination to: (a) a first doped area of a Si layer of a PS, (b) a second doped area of the Si layer of the PS, which has the opposite doping polarity, and (c) a doped area of a Ge area of the PS, which is connected to the Si layer such as to allow transmission of charge carriers from the Ge area to the Si layer. The provision of the first voltage combination forces charge-carriers of the same polarity as the second doped area to move from the Ge area toward the second doped area of the Si layer, where the CCSP are collected via a readout electrode which is electrically coupled to the second doped area. Stage 6310 includes providing the first voltages combination for a sampling duration of the PS.

Stage 6320 includes providing a second voltages combination to: the first doped area of the Si layer, to the second doped area of the Si layer of a PS, and to the doped area of the Ge area. The provision of the second voltage combination diminishes the forcing of the aforementioned charge carriers, thereby ceasing the collection of signals by the PS. Stage 6320 includes providing the second voltages combination for a rest duration of the PS. While not necessarily so, the rest duration may start directly when the sampling duration ends.

The first voltages combination and the second voltages combination may differ from each other in: (a) the voltage(s) applied to the first doped area of the Si layer; (b) the voltage(s) applied to the second doped area of the Si layer; (c) the voltage(s) applied to the Ge area; or (d) any combination of two or more of (a), (b) and (c). At least in the first voltages combination, a photodiode which includes the first doped area and the second doped area is biased for collection of charge carriers resulting from absorption of photons.

Optionally, diode 6230 is maintained in reverse bias during the sampling duration, and optionally during the entire continuous operation of PS 6202. Diode 6230 is maintained in reverse bias when V_{C} is greater than V_{A}. Optionally, Diode 6230 is maintained at zero bias (or substantially zero bias) during the sampling duration, and optionally during the entire continuous operation of PS 6202. Optionally, V_{C}≥V_{A} during the sampling duration, and optionally during the entire continuous operation of PS 6202.

Stage 6330 of method 6300 includes reading by a readout circuit electrically connected to the PS an electric signal collected at least during the sampling duration, for determining a detection signal for the PS for the specific sampling duration. Stage 6330 is executed after stage 6310 is concluded. Stage 6330 may be executed during stage 6320 and/or after it. The detection signal may be used, for example, for generating an image, by combining detection signals of a plurality of PSs, each being directed to an instantaneous FOV within a FOV of a system.

Stages 6310, 6320, and 6330 may be repeated as a group, each time collecting a different detection signal corresponding to the amount of IR light impinging on the Ge area of the IR photodetecting system. The sampling duration and the rest duration may be kept the same between any two consecutive instances of the repetition, but one or both of those duration may also change.

Stage 6310, 6320 and 6330 may be executed for each out of a plurality of PSs of the IR sensor, and method 6300 may include generating an image (or other detection model such as a depth map of a lidar, or spectrograph analysis) representing objects in the FOV in response of the detection signals of the different PSs. The sampling durations of the different PSs may coincide or differ from one another.

A method for detecting IR radiation by a PS such as PS 6202 is disclosed, the method including the following stages:
a. providing first area voltage to a first doped area of a PS and providing second area voltage to a second area of the PS which includes: (a) a Ge photosensitive area, operable to generate e-h pairs in response to impinging IR photons, the Ge photosensitive area including an absorber doped area having a first polarity; and (b) a Si layer including a diode, the diode including the first doped area of the first polarity and the second doped area of a second polarity opposite to the first polarity; wherein the first doped area is located between the second doped area and the absorber doped area.
b. While providing the first area voltage and the second area voltage, providing to the Ge area for a sampling duration of the PS an activation voltage which forces charge carriers of the second polarity to move from the Ge area toward the photodiode where the CCSP are collected via a readout electrode electrically coupled to the second doped area.
c. Upon ending of the sampling duration, providing to the Ge area a rest voltage which diminishes the forcing of the CCSP toward the photodiode, thereby ceasing the collection of signals by the PS.
d. Optionally, reading by a readout circuit electrically connected to the PS an electric signal collected at least during the sampling duration, for determining a detection signal for the PS for the specific sampling duration.
e. Any stage or variation discussed with respect to method 6300.

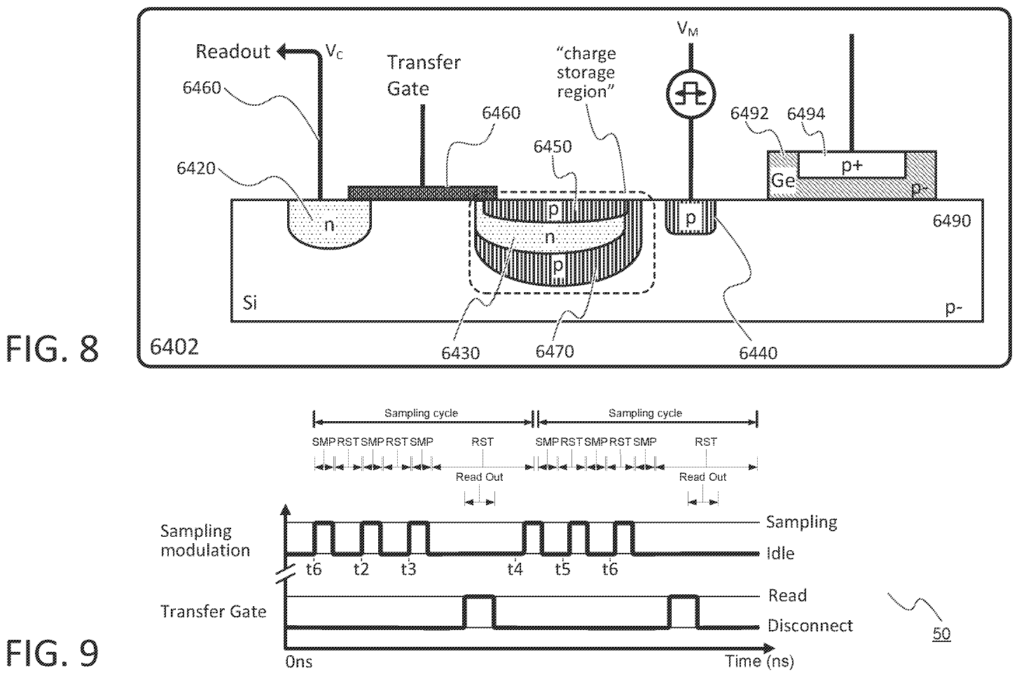

FIG. 8 is a cross section diagram illustrating an example of a PS 6402 of an IR photodetecting system, in accordance with examples of the presently disclosed subject matter. PS 6402 is similar to PS 6202, with a different readout mechanism. While in PS 6202 the readout is implemented via an electrode connected to a pole of the photodiode (of the second polarity), in PS 6402 the readout is implemented via a transfer gate 6410, which connects between storage well 6430 (of the second polarity) and floating diffusion 6420 (of the second polarity). Charge carriers that are generated in the Ge area 6492 (especially in the doped area 6494 of the Ge area 6492) are selectively mobilized to storage well 6430 during an active period of the PS, based on voltage differences between the Ge area 6492 and first doped area 6440. During the collection phase, transfer gate 6410 may keep the storage well 6430 separated from floating diffusion 6420, so that all the CCSP which arrive from the Ge area 6492 are collected during a sampling time of the PS. At a later time (such as during an off time during a modulated voltage) transfer gate 6410 may connect storage well 6430 and floating diffusion 6420, so that charge collected at storage well 6430 may move to floating diffusion 6420, from where it is read out by at least one electrode 6460. Storage well 6430 may be a pinned layer (also referred to as “pinned area”), below a pinning layer 6450 (also referred to as “pinning area”) of the opposite polarity (the first polarity). A third layer 6470 (also referred to as “third area 6470”) may optionally be pinned below storage well, having a different doping of the first polarity with respect to the Si layer in which it resides.

In the illustrated example, the modulation is implemented on the first doped area 6440, while the voltages on the Ge area 6492 and the readout electrode are maintained constant. It is nevertheless noted that any suitable type of modulation may be used, modulating the voltages on any one or more of these electrodes, as long as the relative voltages between the electrodes change over time.

It is noted that while the “charge storage region” may seem like a pinned photodiode, the collected charge arrives from the remote Ge area, in comparison to any part of the charge storage region. Suitable filters may be implemented to present charge generation in the Si (e.g., shielding some parts of PS 6402, spectral band-path or high-pass filters permitting SWIR light but not visible or NIR light to pass, and so on).

FIG. 9 includes states diagram 50 illustrating states applied to the voltage modulation on one or more of the electrodes connected to the Ge area and to the first doped area (sampling mode vs. idle mode) and states applied to the transfer gate (connected, i.e., reading out charge, or disconnected), during consecutive sampling cycles, in accordance with examples of the presently disclosed subject matter. In the illustrated example, several illumination pulses are emitted (in times t1-t6), and the charge indicative on the amount of reflected light of each pulse is accumulated for three consecutive pulses before being read from the storage well via the floating diffusion. The sampling window may start upon the emission of the pulse (e.g., as is the case in the pulses emitted in t1, t2, and t3) or after a delay period (e.g., as is the case in the pulses emitted in t4, t5, and t6), or even before the emission of the pulse. It is noted that some sampling duration may be executed without a connection to a pulse (e.g., for measuring a dark calibration frame). The sampling cycles may be of the same duration, e.g., as exemplified in FIG. 9, but this is not necessarily so. The sampling durations of the different sampling cycles may be constant, e.g., as exemplified in FIG. 9, but this is not necessarily so. The rest durations of the different sampling cycles may be constant, e.g., as exemplified in FIG. 9, but this is not necessarily so. The duration of the sampling cycles may optionally be determined with respect to a frame rate of an IR system of which PS 6402 is a component. For example, for a 60 fps frame rate, the duration of the sampling cycles may be 1/60 seconds each, each including charge collected from one or more pulses. If each frame of the 60 fps example require multiple exposure, the sampling cycles may be much shorter, and not necessarily of equal lengths. The sampling cycles may optionally be synchronized with illumination by an associated illumination source (if any). For example, the IR system may be combined with at least one illumination source (e.g., laser, light emitting diode—LED) in a single electrooptical system (e.g., camera, LIDAR, spectrograph), and the sampling duration may start upon emission of light by the at least one light source. Each sampling duration may be associated with a single illumination span, with a plurality of illumination spans (e.g., in some pulsed illumination implementation), and may also be unsynchronized with illumination (e.g., if no illumination or if constant illumination is implemented). The sampling durations and/or the sampling cycles of different PSs 6402 may be synchronized (e.g., starting at the same time), cascaded (e.g., different rows of PSs in a photodetecting array may be triggered one after the other), or otherwise modulated. The sampling duration may change in different embodiments of the disclosure. Optionally, one or more of the at least one sampling duration of PS 6202 is shorter than 10 nanoseconds. Optionally, one or more of the at least one sampling duration of PS 6202 is between 10-100 nanoseconds. Optionally, one or more of the at least one sampling duration of PS 6202 is between 100-500 nanoseconds. Optionally, one or more of the at least one sampling duration of PS 6202 is between 0.5-5 microseconds. Optionally, one or more of the at least one sampling duration of PS 6402 is longer than 5 microseconds.

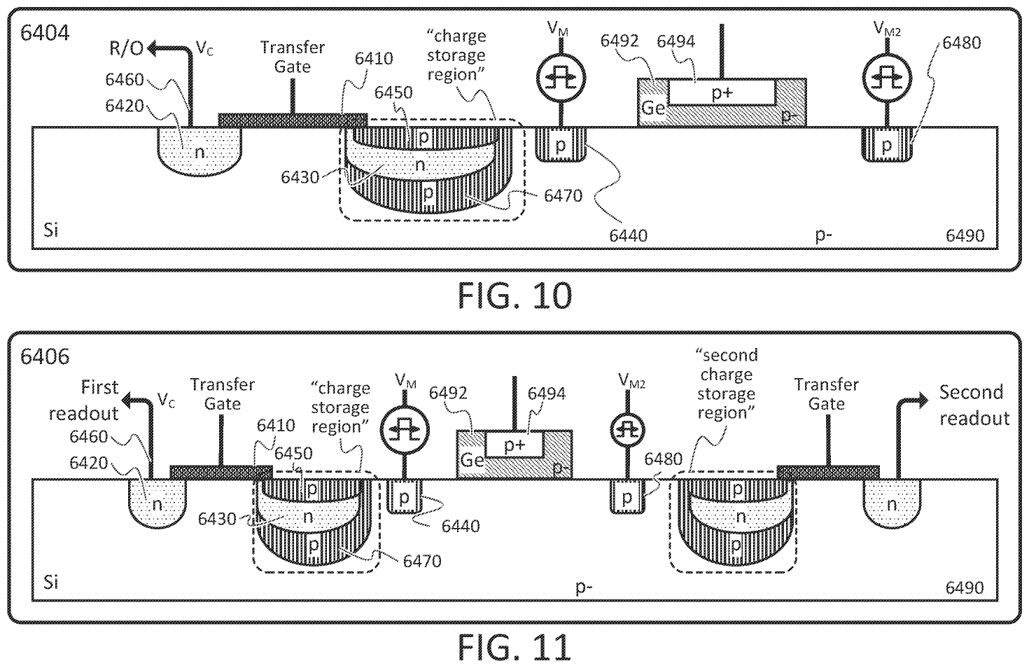

FIG. 10 illustrates PS 6404, in accordance with examples of the presently disclosed subject matter. All the components of PS 6402 discussed above are included in PS 6404, and it includes an additional doped area 6480 which is also modulated with respect to the Ge area, and may be used to turn charge carriers of the second polarity away from the storage well 6430 at idle times of the sampling cycles (e.g., doped area 6480 may be “ON” at all times in which doped area 6440 is “OFF”, and vice versa, but other modulations may also be implemented). It is noted that optionally, additional doped area 6480 is not modulate with respect to the Ge area, but rather have a relatively small constant voltage difference from the Ge area. During idle times, this low DC offset is sufficient to attract the respective charge carriers, but is overridden by the higher modulated voltage during sampling durations. It is noted that a similar additional doped area with corresponding modulation may also be implemented in PS 6402 (exemplified optionally in FIG. 2, denoted V_{R} for “removal” of charge).

FIG. 11 illustrates photosite 6406, in accordance with examples of the presently disclosed subject matter. All the components of PS 6404 discussed above are included in PS 6404, and it includes an additional storage, floating diffusion, readout electrode and other components, for reading out charge carriers of the second polarity when they are mobilized away from the first storage well 6430. Such an arrangement may be used, for example, for time-of-flight measurements, in which the relative amounts of charge collected in each of the two sides may be indicative of a phase of returning light, and thus of the distance to the object from which light is reflected. A controller may toggle the readout between the two readout compounds (left and right of the Ge area, in the diagram).

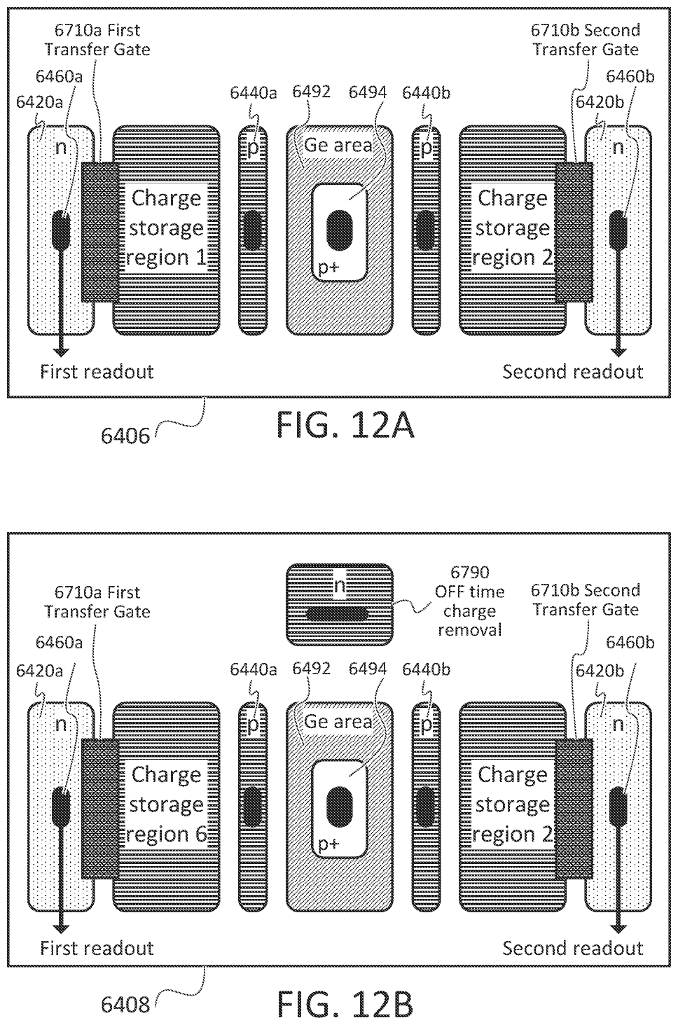

FIG. 12A is a top view illustration of an example of PS 6406 (showing only some of the components, for reasons of clarity). Voltages applied to the different doped areas are transmitted via the respective electrodes (or combinations of electrodes).

FIG. 12B is a top view illustration of an example of PS 6408 (showing only some of the components, for reasons of clarity). Voltages applied to the different doped areas are transmitted via the respective electrodes (or combinations of electrodes). All of the components of PS 6406 discussed above are included in PS 6408, and it includes an additional doped area 6790 (further denoted “OFF time charge removal”) which is also modulated with respect to the Ge area 6492, and may be used to turn charge carriers of the second polarity away from both of the storage wells at idle times of the sampling cycles. For example, charge carriers of the second polarity may be toggled between the first and second storage wells when the reflected pulse of light is detected by PS 6408, and turned towards the third doped area (at the top of the diagram) when no reflected pulse is expected or desired. The transfer gates may be turned on for readout when charge is directed towards that third doped area—either concurrently (e.g., if two readout circuitries are used) or consecutively (e.g., if a single readout circuitry reads both sides at different times).

It is noted that any variation, implementation, feature, and component discussed above with respect to PS 6202 may be applied, mutatis mutandis to PSs 6402, 6404, 6406, and 6408. It is noted that any variation, implementation, feature, and component discussed above with respect to IR system 6200 may be implemented, mutatis mutandis, for any IR system in which PSs 6402, 6404, 6406, or 6408 are implemented.

FIGS. 13A, 13B, and 13C illustrate a cross-section view (FIG. 13A) and a top view (FIG. 13B) of an example of photosite 6502, in accordance with example of the presently disclosed subject matter. Like the PSs discussed above, a group of one or more PSs 6502 may be integrated in an IR photodetecting system operable to detect IR radiation. Such a system may be substantially similar to system 6299, but with PSs 6502 instead of PSs 6202, mutatis mutandis. Each PS 6502 includes a Ge photosensitive area 6520, operable to generate e-h pairs in response to impinging IR photons. Ge photosensitive area 6520 includes an absorber doped area 6522 which is doped with a first polarity (e.g., positively charged). Each PS 6502 also includes Si layer 6510 in which multiple readout structures 6570 are implemented, each readout structure 6570 including: (a) a remote doped area 6534 doped with a second polarity, and (b) an intermediary doped area 6532 positioned between the respective remote doped area 6534 and Ge photosensitive area 6520 (optionally, between absorber doped area 6522 and the respective remote doped area 6534). Intermediary doped area 6532 being doped with a second polarity opposite to the first polarity. Intermediary doped area 6532 of a specific readout structure 6570 is positioned between the respective remote doped area 6534 and Ge photosensitive area 6520 if at least a part of Intermediary doped area 6532 is positioned on a straight line between a first point on the respective remote doped area 6534 and a second point on Ge photosensitive area 6520. Optionally, for each location Lₙ on at least half of an Intermediary doped area 6532 (or even on a larger part of that intermediary doped area 6532, e.g., >60%, >70%, >80%, >90%, >95%), a point Aₙ on the respective remote doped area 6534 and a point Bₙ on the Ge photosensitive area 6520 can be selected such that the location Lₙ is positioned on a straight line connecting these two points (Aₙ and Bₙ).

It is noted that while the operation of PS 6502 is different than that of PS 6202, each readout structure 6570 in combination with GE photosensitive area 6520 may be operated—usually only during part of the runtime of PS 6502—similarly to the Ge area 6220, first doped area 6232 (which correspond in this aspect to the respective intermediary doped area 6532) and second doped area 6234 (which correspond in this aspect to the respective remote doped area 6534). When operated similarly to PS 6502, the flow of charge carriers between the Ge area and the respective readout structure 6570 behaves similarly to the sampling phase of PS 6502 (even though differences are possible, e.g., during to affect of the other readout structures 6570, to relative voltages in all of the electrodes, and so on.). Optionally (e.g., as illustrated in FIG. 13C), PS 6502 may include guard ring 6592 (or trenching) which completely, incompletely, or partly surrounds PS 6592 (or parts thereof). Many uses and ways of implementations are known to a person who is of skilled in the art, and are not disclosed here for reasons of brevity.

The IR system in which PS 6502 further includes a controllable power source (partly represented by controllable power units 6540) which is operable to provide controlled voltages to the Ge photosensitive area 6520 (possibly to a part of it, such as absorber doped area 6522), as well as to the remote doped areas 6534 and the intermediary doped areas 6532 of different readout structures (e.g., all of them). The voltages may be provided to the different areas via suitable electrodes, such as (but not limited to) electrodes 6535, 6533, and 6521. It is noted that some of the areas to which voltages are supplied by the controllable power source may receive constant (or substantially constant) voltages, but for at some of these areas, controllable (e.g., modulated) voltages which change with time are provided. In the example illustrated in FIG. 13A, modulated voltages are supplied to intermediary doped areas (6532A and 6532B, in the illustrated example) by variable power units 6540, but this is just an example. As illustrated in the diagram, reading out of the charge from the readout structures 6570 may be done via connection 6560 (e.g., via electrode 6535 through which voltages are applied to the remote doped areas 6534), which may be connected, for example, to a readout circuit of the IR electrooptic system in which PSs 6502 are integrated. In a sampling duration of a readout structure 6570 (see further examples below), charge carriers of the second polarity are repelled by the voltage applied to Ge area 6522 and are attracted to the voltage applied to the active intermediary doped area 6532. These charge carriers move past the active intermediary doped area 6532 toward remote doped area 6234 of the active readout structure 6570 using a drift velocity (e.g., resulting from the applied voltage between the intermediary doped area and the remote doped area, e.g., in an optional depletion region 6580 (which is exemplified only in FIG. 13A).

FIG. 13D illustrates an example of PS 6502 with four separate readout structures 6570, numbered 6570A, 6570B, 6570C, and 6570D. As exemplified in FIG. 13D, optionally PS 6502 may include a plurality of readout modules 6598, each associated with one or more readout structures 6570, which is operable to apply signal processing to the signal provided by the respective readout structure 6570. Such signal processing may include, for example, amplification, noise cancelation, and any other suitable signal processing technique. Alternatively or additionally, PS 6502 may include a plurality of modules which affect the signal collection by the specific PS (e.g., in the location of modules 6598 in the diagrams), such as modules which amend the controlled voltages supplied to a plurality of PSs 6502 (e.g., a row of a sensor array) for the requirements of the specific PS 6502 (e.g., depending on the temperature of the specific PS, on its characteristic dark noise, and so on). Optionally, PS 6502 may include internal trenches 6596 (or guard ring) which electrically separates readout structures 6570 from readout modules 6598, or other modules as discussed above.

Reverting to the controllable power source, it is noted that different voltage schemes may be applied by the controllable power source to the different electrodes of any one or more PS 6502, in order to alternately read charge (and by that alternately reading detection signals) by different readout structures 6570 of any such single PS 6502. For example, controllable power source of PS 6502 may optionally be operable (e.g., by way of being previously configured, by a run-time decision of a controller, etc.) to maintain the following voltages schemes, e.g., for achieving the aims discussed below. It is noted that the reference numbers in the following discussion are given as a non-limiting example pertaining to FIGS. 13B, 13C and 13D:
a. For a first sampling duration:
   1. Maintain relative voltages on: (a) Ge photosensitive area, (b) a first remote doped area of a first readout structure out of the multiple readout structures, and (c) a first intermediary doped area of the first readout structure, such that charge carriers of the second polarity are forced to move from the Ge area toward the first readout structure by a first pulling force, where the CCSP are collected via a first readout electrode electrically coupled to the first remote doped area; and
   2. Maintain voltages on the doped areas of a first group of readout structures that includes the rest of the multiple readout structures other than the first readout structure (e.g., one readout structure in the example of FIG. 13B, three readout structures in the example of FIG. 13D), such that a pulling force applied to charge carriers of the second polarity towards each of the remote doped areas of the first group of readout structures is less than half of the first pulling force.
b. For a second sampling duration (which is later than the first sampling duration, but not necessarily directly after it):
   1. Maintain relative voltages on the Ge photosensitive area, a second remote doped area of a second readout structure out of the multiple readout structure and a second intermediary doped area of the second readout structure, such that charge carriers of the second polarity are forced to move from the Ge area toward the second readout structure by a second pulling force, where the CCSP are collected via a second readout electrode electrically coupled to the second remote doped area; and
   2. Maintain voltages on the doped areas of a second group of readout structures that includes the rest of the multiple readout structures other than the second readout structure, such that a pulling force applied to charge carriers of the second polarity towards each of the remote doped areas of the second group of readout structures is less than half of the second pulling force.
c. For a third sampling duration (which is later than the second sampling duration, but not necessarily directly after it):
   1. Maintain relative voltages on the Ge photosensitive area, the first remote doped area and the first intermediary doped area, such that charge carriers of the second polarity are forced to move from the Ge area toward the first readout structure by a third pulling force, where the CCSP are collected via the first readout electrode; and
   2. Maintain, for the third sampling duration, voltages on the doped areas of the first group of readout structures, such that a pulling force applied to charge carriers of the second polarity towards each of the remote doped areas of the first group of readout structures is less than half of the third pulling force.

The alteration between reading from the first readout structure and the second readout structure may continue of the same principle. It is noted that the disclosed process may also be fitting for reading out of more than two readout structures (e.g., four readout structures in the example of FIG. 13D). The additional readout structures may be read from, for example, between stage b2 and stage c1. During the reading out, similar voltage scheme may be applied to a selected readout structure (e.g., similarly to stage b1, mutatis mutandis) and a respective group of remaining readout structures (e.g., similarly to stage b2, mutatis mutandis). It is noted that in PSs 6502 which include more than two PSs, a cyclical read out order may be kept (e.g., ABCDABCDABCD), but this is not necessarily so, and any other order for reading out from different readout structures 6570 may be implemented (e.g., ABCDBDACDABC, ABABCDCDABABCDCD). Additionally, optionally, controllable power module may apply suitable voltages for reading out of two or more readout structures 6570 concurrently (e.g., 6570A and 6570B), while reducing the pulling force towards the one or more remaining photosite structures (e.g., 6570C and 6570D). The sampling cycles may be of the same duration, but this is not necessarily so. The sampling durations of the different readout structures may be identical to one another, but this is not necessarily so.

Referring to the pulling forces discussed above, it is clear that different charge carriers will face different pulling forces toward a doped area, even concurrently (e.g., when known voltages are supplied to the different parts of PS 6502). However, a single charge carrier will face different pulling forces towards the different readout structures 6570, and the relative magnitudes of these forces applied to any given charge carriers may be compared.

While the FIGS. Illustrating PS 6502 illustrate a polarity in which absorber doped area 6522 is doped with a positive polarity, it is noted that reverse polarities may also be implemented (i.e., absorber doped area 6522 is doped with a negative polarity, and the rest of the polarities in PS 6502 are also reversed). It is noted that while PS s 6502 and 6202 are different from one another, a person who is of skill in the art will be able to implement the expanded description of PS 6202, its components, and its ways of operation, for understanding PS 6502, its components, and its ways of operation, mutatis mutandis.

As exemplified in the nonlimiting example of FIG. 13B, PS 6502 may include optional doped area 6590 which is also modulated with respect to the Ge area 6520, and may be used to turn charge carriers of the second polarity away from the reading structures 6570 (e.g., at idle times of the sampling cycles). For example, charge carriers of the second polarity may be toggled between reading structures 6502 when the reflected pulse of light is detected by PS 6502, and turned towards the doped area 6590 when no reflected pulse is expected or desired. Optionally, a doped area of the opposite polarity (denoted 6594) may be located between Ge area 6520 and doped area 6590, and the voltages applied to doped area 6590 and 6594 (e.g., via electrodes connected thereto, not numbered in the diagram) may be applied similarly to a readout structure 6570. That is, structure 6588 which includes areas 6590 and 6594 may optionally be operated similarly to a readout structure 6570 (e.g., when discarding of charge is needed), where doped area 6590 corresponds to area 6534, and area 6594 corresponds to 6532.

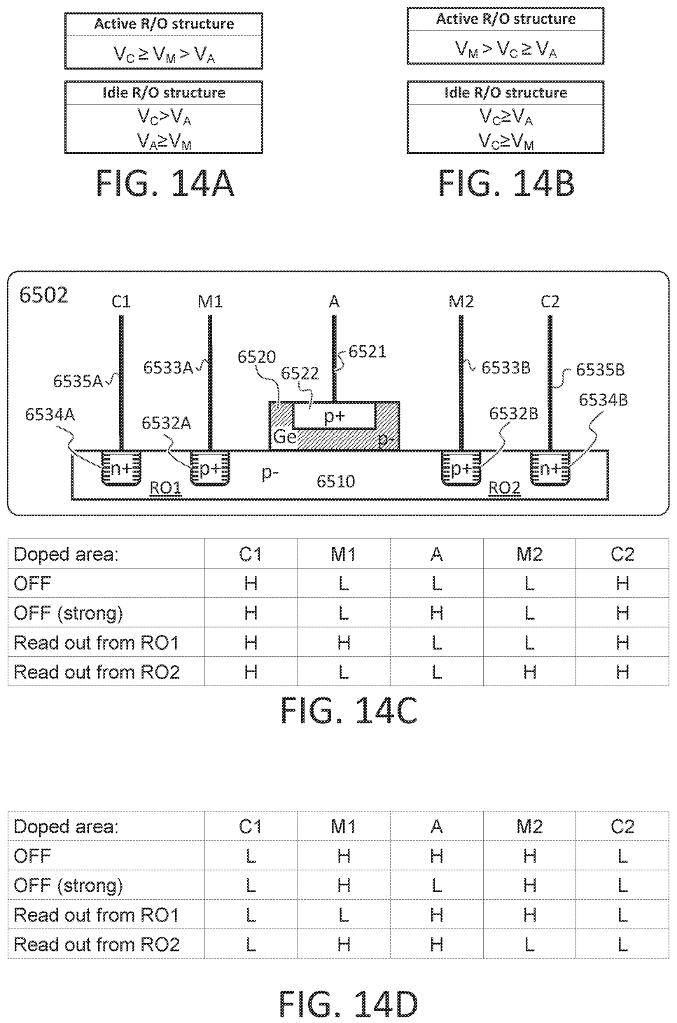

FIG. 14A illustrates relative voltages which may be applied to different areas of a PS 6502 during its operation. V_{A} is the voltage supplied to Ge area 6520 (or part thereof), which may serve as an anode. V_{A} is the voltage supplied to Ge area 6520 (or part thereof), which may serve as an anode. V_{C} is the voltage supplied to remote doped area 6534 (or part thereof) of a specific readout structure 6570, which may serve as a cathode. V_{M} is the voltage supplied to intermediary doped area 6532 (or part thereof), which may serve as a controllable motion inducing structure. When a readout structure is in active detection mode (e.g., corresponding to stages a and c of the first readout structure, as discussed above), the relationship between the voltages applied to Ge area 6520 and to the different doped areas of that readout structure 6570 may conform to the following rule: V_{C}(active)≥V_{M}(active)>V_{A} (active), while for the nonactive readout structures at the same time, the following rule may apply: V_{C}(nonactive)>V_{A}(nonactive) and V_{A} (nonactive)≥V_{M}(nonactive). The rules of FIG. 14A are relevant to the doping polarities illustrated in FIGS. 13A through 13D. If the opposite doping polarities are implemented (e.g., when doped area 6522 is negatively doped), the rules of FIG. 14B may be used. FIG. 14C illustrates exemplary relationships between the voltages applied to the different electrodes (denoted on the diagram on the top as C1, M1, A, M2, and C2) when PS 6502 does not read at all (two examples are given, denoted “OFF” and “OFF strong”), when reading out is done via the left readout structure (denoted “Read out from RO1”), and reading out is done via the right readout structure (denoted “Read out from RO2”). H represent high voltage, and L represent a lower voltage. It is noted that some differences may be implemented between different areas which are assigned the same representative voltage symbol (i.e., “H” or “L”). For example, in an active readout structure, different voltages may be applied to C1 and to M1 (e.g., 1.7 Volt and 1.8 Volt), in order to increase the number of charge carriers of the second polarity which are detected at the remote doped area. Referring to the voltages applied to the different areas of PSs 6502 (as well as the other PSs described in the present description), it is noted that different levels of voltage may be used in different implementations. Exemplary voltages may be in the order of magnitude of 1V to 10V, but this is not necessarily so. For example, voltages applied to different doped areas on the PS may be in any one or more of the following ranges (where ±represents a positive or negative voltage, depending on the implementation): 0V-±0.25V, ±0.25V-±0.5V, ±0.5V-±1V, ±1V-±1.5V, ±1.5V-±2.5V, ±2.5V-±5V, and ±5V-±10V. Other voltages may also be applied. Referring to the examples of FIG. 14C, by way of example, low voltages (denoted “L”) may be in the range of 0V-0.25V, while high voltages (denoted “H”) may be in the range of 1V-1.5V. In the description above, the voltages applied to the different PSs where described based on the force applied to charge carriers in the PSs, as a result of the respective voltages. However, the voltages may also be defined more directly. For example, the voltage applied to a modulated electrode of an active readout structure 6570 (e.g., to the intermediary doped area, in the example of FIG. 14C) during a sampling duration (e.g., the first sampling duration, or any other sampling duration) may be is at least ten times higher than any voltage applied to a modulated electrode (e.g., any intermediate doped area) of the first group of readout structures averaged over the respective sampling duration (which are in idle mode, for example). This relationship between voltages may be implemented in PS 6502 even if the pulling forces applied to the charge carriers are different than the ones discussed above, mutatis mutandis.

PS 6502 include a single Ge area 6520 with one (or more) associated electrode 6521 connected thereto. However, unlike PS 6502 which includes only a single anode and a single cathode, PS 6502 includes a plurality of sets of first doped area 6532 and second doped area 6534, as well as associated components (e.g., electrodes). Each set of doped areas and associated elements is denoted with a suffix of a capital letter associated with the set. For example, first doped area 6532 of set A is denoted 6532A, and first doped area 6532 of set B is denoted 6532B. It is noted that while the diagram shows only a single combination of polarities, other combinations of polarities of doped areas and charge carriers may also be implemented, and especially one with the opposite polarities. It is noted that the polarities of the doped areas of different readout structures may different between one readout structure to another in a single PS 6502.

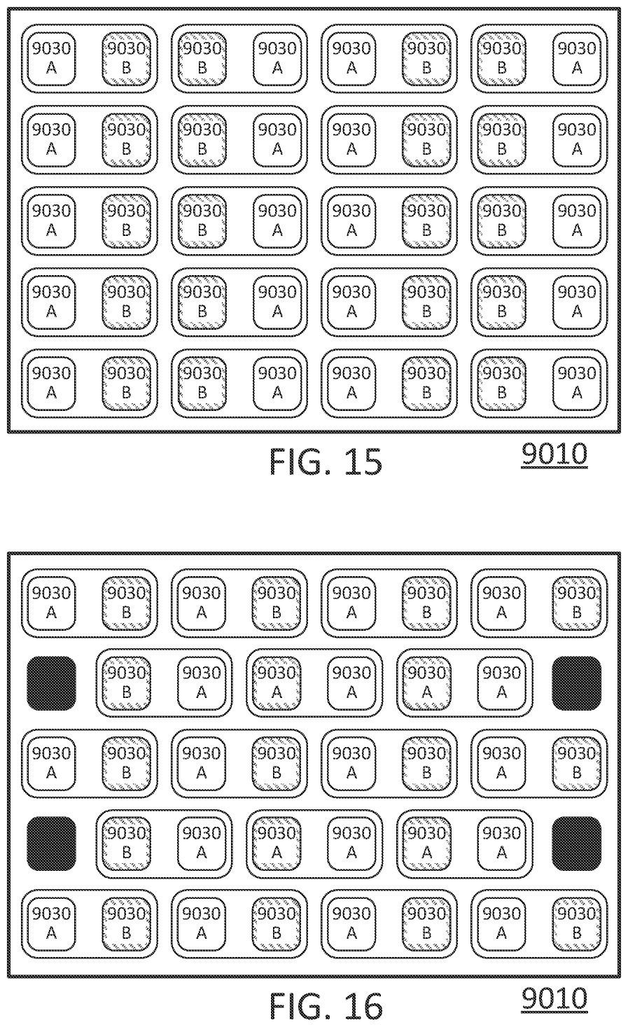

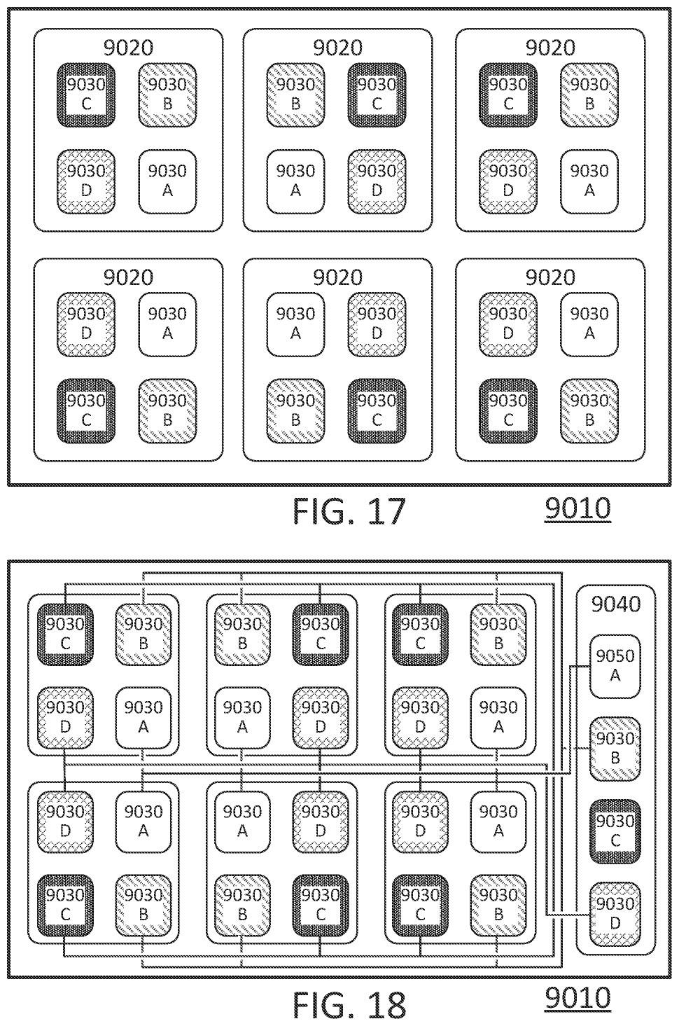

FIGS. 15, 16, 17, and 18 illustrate photodetector arrays 9010 having N-tap PSs 9020, in accordance with examples of the presently disclosed subject matter. FIGS. 15 and 16 illustrate examples of 2-tap PDAs 9010, in which each photosite have two detection structures 9030 which are activated alternately, and FIGS. 17 and 18 illustrate examples of 4-tap PDAs 9010, in which each photosite have four detection structures 9030 which can be activated in a round robin fashion, or in any other fashion. It is noted that the following discussion may be applied to PDAs 9010 with 3-tap PSs 9020, 8-tap PSs 9020, or any other N-tap PSs, where N is a natural number greater than 1. The PSs 9020 may be, for example, PSs 9502 or other types of multi-tap photosites discussed in this disclosure, or any other type of N-tap photosite (e.g., a silicon-only N-tap photosite for the visible range of the electromagnetic spectrum).

Prior art implementations of photodetector arrays with N-tap photosites have been implemented in rectangular tiling, in which each PS is identical to its neighbors, and the different detection/readout structures of the different PS are activated in identical manner in all of the PSs of the array (e.g., for a four-tap PDA, activating all of the top-left detection structures of the different PSs concurrently, followed by activating all of the top-right detection structures of the different PSs concurrently, followed by activating all of the bottom-right detection structures of the different PSs concurrently, followed by activating all of the bottom-left detection structures of the different PSs concurrently, for a synchronized clockwise modulated detection scheme). FIGS. 15 through 18 illustrate PDA 9010 with N-tap PSs 9020 whose readout structures 9030 are activated in non-identical fashion. FIG. 18 illustrate a possible circuitry for controlling the PSs 9020 of a 4-tap PDA 9010 of method 9060 discussed below.

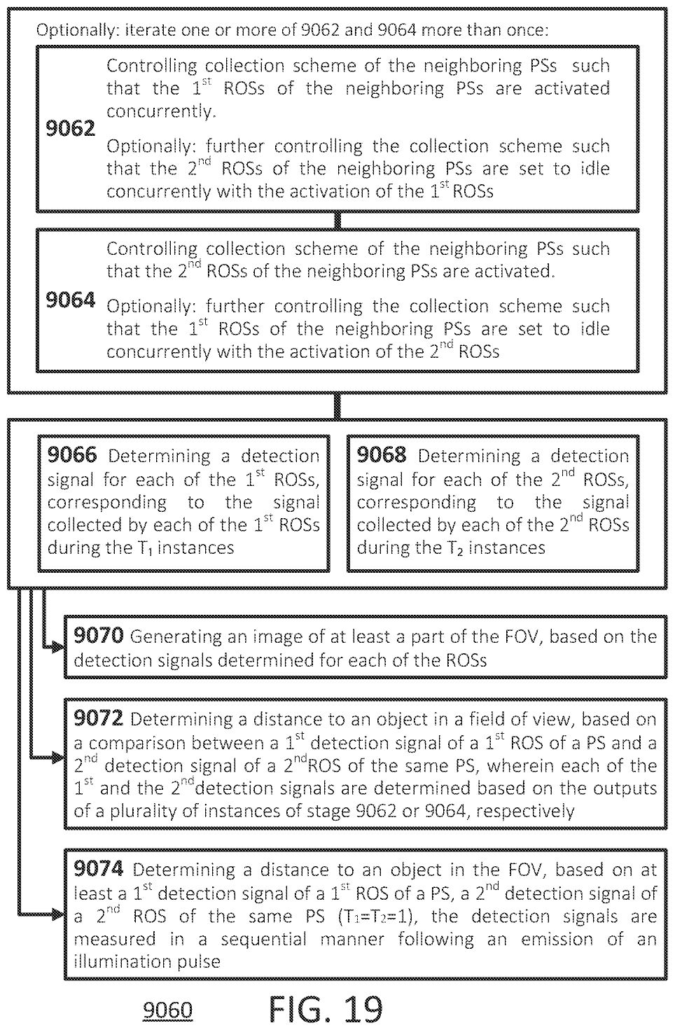

FIG. 19 illustrates, in accordance with examples of the presently disclosed subject matter, method 9060 for detecting light arriving from a field-of-view of a PDA which includes a plurality of PSs, each PS including multiple readout structures which are operable to collect charge carriers generated by the PS in response to light impinging on the reflective PS, where different readout structures of any single PS can be controlled to collect different momentarily levels of signal in response to light impinging on the PS instantaneously (e.g., as discussed above with respect to PSs 9502). Referring to the examples set forth with respect to the previous drawings, the PSs may be PSs 9502, or any type of N-tap Si PSs (which do not include Ge).

The following discussion pertains to neighboring photosites, each including at least a first readout structure (e.g., 9030A) and a second readout structure (e.g., 9030B), where the first readout structures of the neighboring photosites are adjacent to each other, and the second readout structures of the neighboring photosites are distanced from one another. For example, a distance between the second readout structures of the neighboring PSs may be at least 3 times larger than a distance between the first readout structures of the neighboring PSs. For example, the distance between the second readout structures of the neighboring PSs may be larger than the distance between the first readout structures of the neighboring PSs by at least one (or at least two) width of a readout structures. For example, the distance between the second readout structures of the neighboring PSs may be larger than a width of a PS of the PDA.

Stage 9062 includes controlling collection scheme of the neighboring PSs (e.g., by applying suitable voltages to different areas of the PS, including different parts of the different readout structures), such that the first readout structures of the neighboring PSs are activated (i.e., set to detection mode) concurrently. Optionally, stage 9062 may also include controlling the collection scheme of the neighboring PSs such that the second readout structures of the neighboring photosites are set to idle (e.g., applying reduced pulling force of charge carriers of a detected polarity towards the second readout structures, or even applying repelling force to such charge carriers away from the second readout structures) concurrently with the activation of the first readout structures.

Stage 9064, which is executed after stage 9062, includes controlling collection scheme of the neighboring photosites (e.g., by applying suitable voltages to different areas of the photosite, including different parts of the different readout structures), such that the second readout structures of the neighboring photosites are activated (i.e., set to detection mode) concurrently. Optionally, stage 9062 may also include controlling the collection scheme of the neighboring photosites such that the first readout structures of the neighboring photosites are set to idle (e.g., applying reduced pulling force of charge carriers of a detected polarity towards the first readout structures, or even applying repelling force to such charge carriers away from the first readout structures) concurrently with the activation of the second readout structures.

Optionally, stages 9062 and 9064 may be iterated to collect additional signal. Optionally, stage 9062 and/or stage 9064 also include controlling the collection scheme of the neighboring photosites such that one or more readout structures of each of the neighboring photosites (e.g., third, fourth, etc., such as 9030C, 9040D) are also set to idle concurrently with the activation of the respective first readout structures or second readout structures. It is noted that for photosites which include more than two readout structures, additional stages, similar to 9062 and 9064, may be included for the additional readout structures, mutatis mutandis. As mentioned above, when photosites with more than two readout structures are implemented, and one or more readout structure are activated more than once in a detection of the photosite (e.g., in a single frame of the PDA), any order may be implemented, whether round-robin or otherwise (e.g., ABCDABCDABCD, ABCDBDACDABC, ABABCDCDABABCDCD). If the different photosites include a structure for discarding of charge carriers without reading it, and without them reaching the other readout structures (e.g., structure 6588 discussed above), an additional optional stage, similar to 9062 and 9064, may be included for driving relevant charge carriers towards this structure, mutatis mutandis.

After stage 9062 has been executed at least once (1≤T₁ times) and stage 9062 has been executed at least once (1≤T₂ times), method 9060 may optionally continue with stage 9066 of determining a detection signal for each of the first readout structures, corresponding to the signal collected by each of the first readout structures during the T₁ instances, and with stage 9068 of determining a detection signal for each of the second readout structures, corresponding to the signal collected by each of the second readout structures during the T₂ instances. The determined detection signals may be combined, for example (e.g., summed) for each detection frame of the PDA.

Method 9060 may optionally continue with at least one of optional stages 9070, 9072, and 9074.

Stage 9070 includes generating an image of at least a part of the FOV of the PDA, based on the detection signals determined for each of the readout structures, wherein the number of detection signals for each photosite is smaller than a number of readout structures of the photosite (e.g., determining a single detection value for each photosite, based on data collected by two, three four, or more readout structures of the photosite). Optionally, stage 9070 may include determining one or more detection signals for a group of photosites, wherein the overall number of detection signals determined for the group of photosites is smaller than the number of readout structures (RO structures, ROS) in each photosite. For example, determined R, G, and B color signals for a group of four N-tap photosites.

Optional stage 9072 includes determining a distance to an object in a FOV, based on a comparison between a first detection signal of a first readout structure of a photosite and a second detection signal of a second readout structure of the same photosite, wherein each of the first detection signal and the second detection signals are determined based on a plurality of measurements executed during a plurality of instances of stage 9062 or 9064, respectively. For example, stage 9072 may be executed by implementing current assisted photonic demodulator (CAPD) techniques, many of which are known in the art.

Optional stage 9074 includes determining a distance to an object in a FOV, based on a first detection signal of a first readout structure of a photosite, a second detection signal of a second readout structure of the same photosite, and possibly additional detection signals of additional readout structures of the same photosite (if any), wherein each detection signal is based on a single instance (i.e., T₁=1, T₂=1, etc.), and each detection signal is measured in a sequential manner (optionally somewhat overlapping), after emission of an illumination pulse, wherein the magnitude of the different detection signals and their temporal relation to the timing of the pulse emission are indicative of the distance to the object. An example is provided below.

It is noted that the concurrent activation of neighboring readout structures of neighboring photosites 9020 may be used in order to reduce cross-talks between adjacent photosite, and reduce the amount of pulling force applied by an active readout structure of a neighboring photosite applied at the opposite direction (or otherwise wrong direction) to the direction of the active readout structure of the present photosite. It is noted that while the second readout structures of method 9060 were described as remote from one another, these photosites may be adjacent to other second readout structures of other neighboring photosites, e.g., as exemplified in FIGS. 15 and 17.

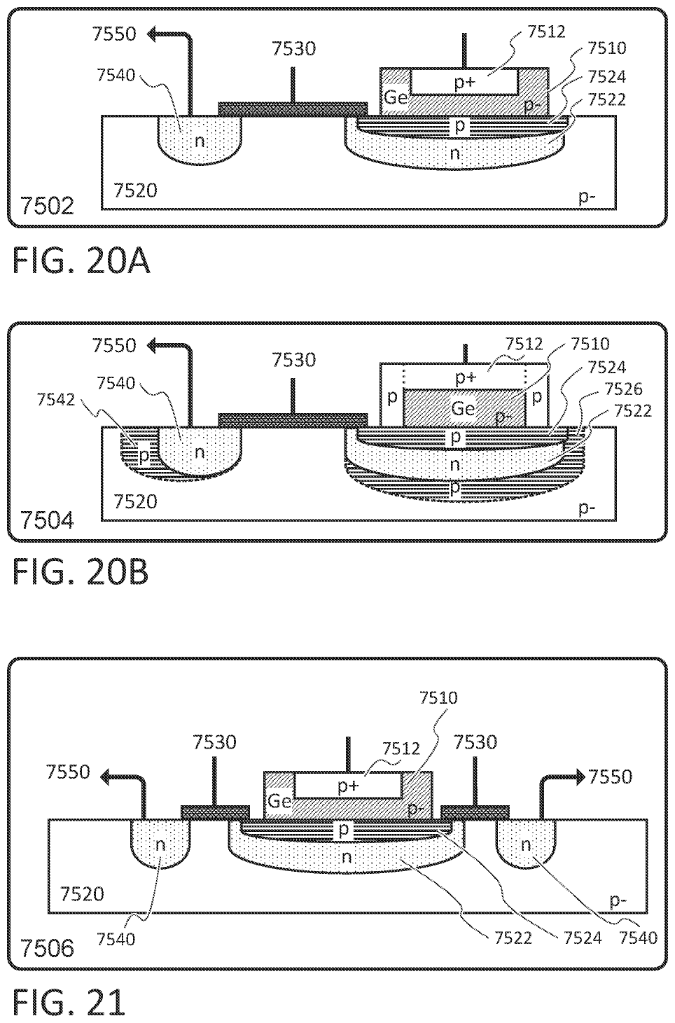

FIGS. 20A and 20B are a cross section diagrams illustrating examples of photosites 7502 and 7504 of IR photodetecting systems, in accordance with examples of the presently disclosed subject matter. Photosites 7502 and 7504 may be combined in any suitable IR photodetecting system discussed above, as well as in any other type of IR photodetecting system which requires one or more photosites (e.g., camera, LIDAR, spectrograph). Both photosite 7502 and photosite 7504 include a Ge area 7510 on top of a Si layer 7520 which includes pinned layer 7522 (a negatively doped layer in the diagrams) and pinning layer 7524 (a positively doped layer in the diagrams). Both pinned layer 7522 and pinning layer 7524 reside partially below Ge area 7510.

Pinned layer 7522 and optionally also pinning layer 7524 are connected via transfer gate 7530 to floating diffusion 7540. Charge carriers that are generated in Ge area 7510 (especially in doped area 7512 of Ge area 7510) are collected at pinned layer 7522 (also referred to as the storage well). During the collection phase, transfer gate 7530 may keep the storage well 7522 separated from floating diffusion 7540, so that all the charge carriers which arrive from Ge area 7510 are collected during a sampling time of the respective photosite. At a later time (such as during an off time of the respective photosite), transfer gate 7530 may connect storage well 7522 and floating diffusion 7540, so that charge collected at storage well 7522 may move to floating diffusion 7540, from where it is read out by at least one electrode. An optional third doped layer 7526 (similar to layer 6470, mutatis mutandis) is exemplified in FIG. 20B. It is noted an inversely doped area 7542 may be positioned adjacent to floating diffusion 7540, e.g., as exemplified in FIG. 20B. A similar inversely doped area may be implemented adjacent to any one or more of floating diffusions 7540 discussed above. Charge can be read from floating diffusion via a suitable readout electrode 7550 which is connected to floating diffusion 7540.

FIG. 20B also illustrates another option of including a doped area 7512 for the Ge area 7510. The Ge area 7510 may optionally include a doped area on any side of the Ge area 7510 (e.g., top, side, rims, etc.), optionally covering the entire exposed surface (i.e., above the Si layer) of the Ge area 7510 or parts thereof. It is noted that a similar implementation of doped areas within the Ge area may also be implemented in any of the aforementioned photosites, mutatis mutandis.

FIG. 21 illustrates photosite 7506, in accordance with examples of the presently disclosed subject matter. All the components of photosites 7502, 7504 discussed above are included in photosite 7506, and it includes an additional floating diffusion 7540, readout electrode 7550 and other components, for reading out charge carriers of the second polarity when they are mobilized away from storage well 7522. Such an arrangement may be used, for example, for time-of-flight measurements, in which the relative amounts of charge collected in each of the two sides may be indicative of a phase of returning light, and thus of the distance to the object from which light is reflected. An example for techniques which may be used for determining distance based on charge collected from different floating diffusions of a single photosite connected to a single Ge area are the aforementioned CAPD techniques. Other examples are provided below. A controller (not shown) may toggle the readout between the two readout compounds (also referred to as “readout structures”, left and right of Ge area 7510, in the diagram). It is noted that while FIG. 21 illustrates photosite 7506 as having two floating diffusions 7540, each connected to the storage well 7522 via a respective transfer gate 7530, it is noted that a photosite 7506 may be implemented with three or more floating diffusions 7540, each connected to the storage well 7522 via a respective transfer gate 7530. For example, three or four floating diffusions may be implemented in a triangular or a rectangular photosite 7506, respectively.

Referring to photosites 6402, 6404, 6406, 6408, 7502, 7504, and 7506 (and all the other photosites discussed above), it is noted that the same photosites may be implemented with the inverted polarities to the ones exemplified in the illustrations. That is, areas/parts that are illustrated with negative polarity may be implemented as positively doped, together with implementing as negatively doped areas/parts that are illustrated with positive doping. It is also noted that the doping levels (e.g., −, +, ++) of the different areas may vary in different implementations.

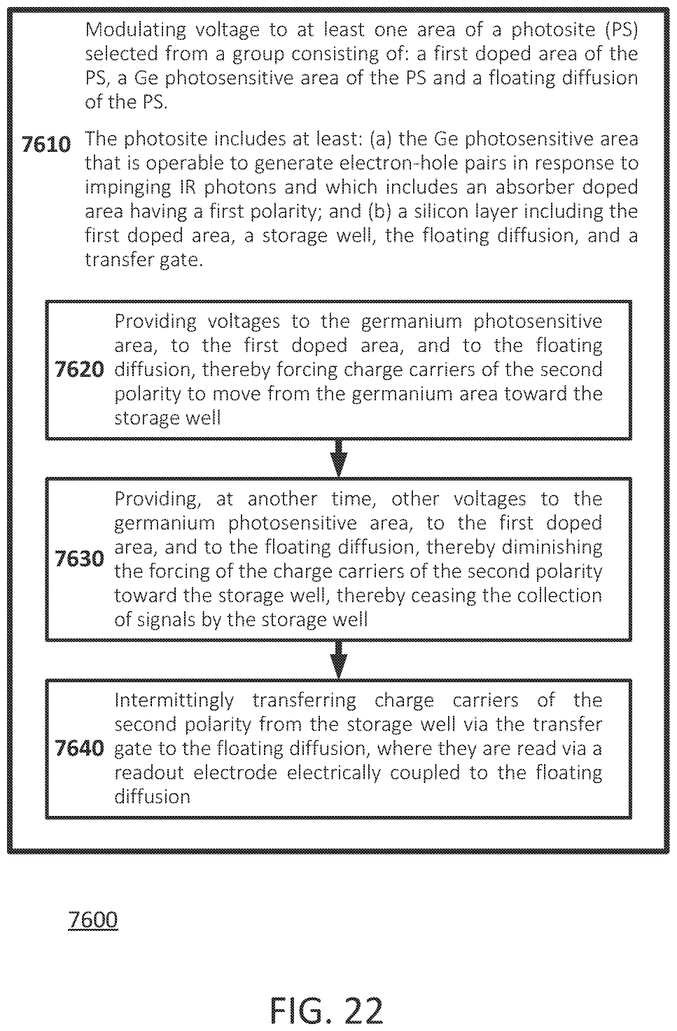

FIG. 22 illustrates a method 7600 for detecting IR radiation, in accordance with examples of the presently disclosed subject matter. Referring to the examples of the accompanying drawings, method 7600 may optionally be carried out by any one of photo sites 7502, 7504, and 7506, mutatis mutandis.

Stage 7610 of method 7600 includes modulating voltage to at least one area of a photosite (PS) selected from a group consisting of: a first doped area of the PS, a Ge photosensitive area of the PS and a floating diffusion of the PS, wherein the photosite includes at least: (a) the Ge photosensitive area that is operable to generate e-h pairs in response to impinging IR photons and which includes an absorber doped area having a first polarity; and (b) a Si layer including the first doped area, a storage well, the floating diffusion, and a transfer gate. The modulating of stage 7610 includes at least the following stages:
Stage 7620 of providing voltages to the Ge photosensitive area, to the first doped area, and to the floating diffusion, thereby forcing charge carriers of the second polarity to move from the Ge area toward the storage well.
Stage 7630 which includes providing, at another time, other voltages to the Ge photosensitive area, to the first doped area, and to the floating diffusion, thereby diminishing the forcing of the CCSP toward the storage well, thereby ceasing the collection of signals by the storage well.
Stage 7640 of intermittently transferring charge carriers of the second polarity from the storage well via the transfer gate to the floating diffusion, where they are read via a readout electrode electrically coupled to the floating diffusion.

Optionally, method 7600 may also include reading by a readout circuit electrically connected to the photosite an electric signal collected at the floating diffusion, for determining a detection signal for the photosite for the specific sampling duration.

The different stages of method 7600 may be executed for each out of a plurality of photosites of the IR sensor, and method 7600 may include generating an image (or other detection model such as a depth map of a lidar, or spectrograph analysis) representing objects in the FOV in response of the detection signals of the different photosites. The sampling durations of the different photosites may coincide or differ from one another.

Any variation discussed with respect to photosites 7502, 7504, and 7506 (as well as with respect to equivalent components of any other photosite discussed above) may be implemented, mutatis mutandis, in an execution of method 7600.

When method 7600 is executed for a photosite which includes two or more floating diffusions connected to the Ge area by a respective plurality of transfer gates (e.g., as discussed above with respect to photosite 7506), stages 7620, 7630 and 7640 may be executed for each of the floating diffusions separately (e.g., in an alternating fashion, a round-robin fashion, or in any other desired order). While not necessarily so, after execution of a first instance of stages 7620 and 7630, a first instance of stage 7640 may be executed for transferring charge carriers of the second polarity from the storage well via a first transfer gate to a first floating diffusion, where they are read via a first readout electrode electrically connected to the first floating diffusion. Following the first instance of stage 7640, a second instance of stages 7620 and 7630 may be carried out, following by a second instance of stage 7640 in which charge carriers of the second polarity are transferred from the storage well via a second transfer gate to a second floating diffusion, where they are read via a second readout electrode electrically connected to the second floating diffusion. Later instances of stages 7620, 7630, 7640 may be executed for transferring charge carriers of the second polarity toward additional floating diffusions for the first time, and/or for floating diffusions for an additional time, as required.

Optionally, method 7600 may also include reading by a readout circuit electrically connected to the photosite an electric signal collected at the floating diffusion, for determining a detection signal for the photosite for the specific sampling duration. The detection signal may be used, for example, for determining a brightness value for a pixel in an image of the FOV. If a photosite with multiple floating diffusion is used, an electric signal may be read from each of the floating diffusions via a suitable electrode. These signals may be used, for example, for determining distance to objects in the FOV.

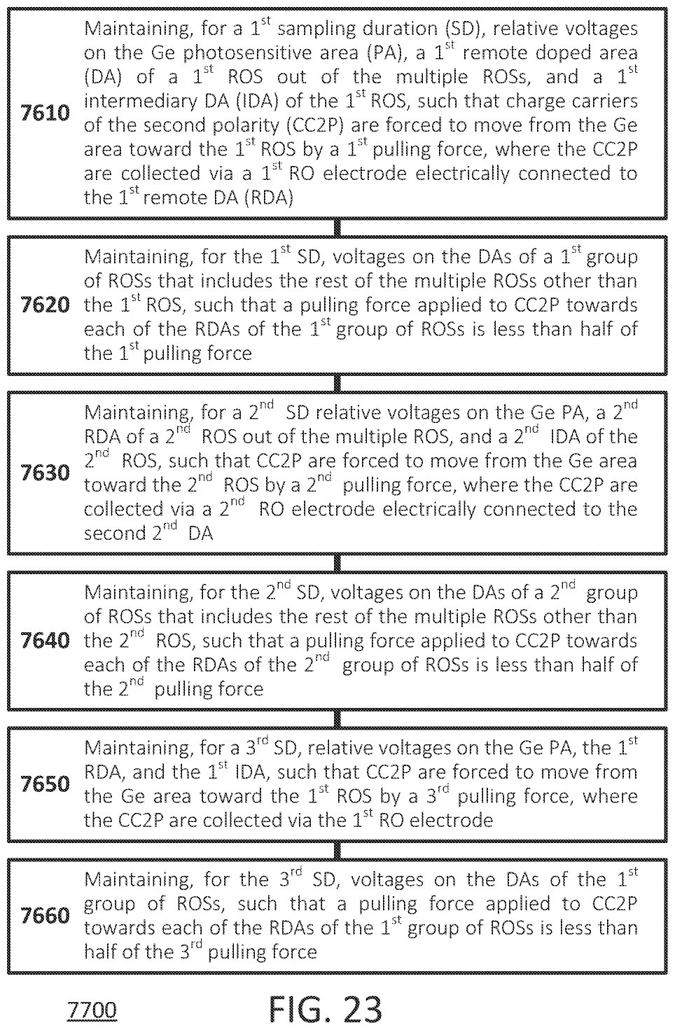

FIG. 23 illustrates method 7700 for detecting IR radiation, in accordance with examples of the presently disclosed subject matter. Referring to the examples of the accompanying drawings, method 7700 may optionally be carried out by photosite 6502.

Method 7700 includes providing controlled voltages to areas of a photosite which includes at least:
a. A Ge photosensitive area that is operable to generate e-h pairs in response to impinging IR photons and which comprises an absorber doped area doped with a first polarity; and
b. doped areas of a multiple readout structures implemented on a Si layer of the photosite, comprising for each of the multiple readout structures: (i) a remote doped area doped with a second polarity, and (ii) an intermediary doped area positioned between the remote doped area and the Ge photosensitive area, the intermediary doped area being doped with a second polarity opposite to the first polarity.

The providing of the controlled voltages is used at different times for different ends, which include at least stages 7710, 7720, 7730, 7740, 7750, and 7760.

Stage 7710 includes maintaining, for a first sampling duration, relative voltages on the Ge photosensitive area, a first remote doped area of a first readout structure out of the multiple readout structures, and a first intermediary doped area of the first readout structure, such that charge carriers of the second polarity are forced to move from the Ge area toward the first readout structure by a first pulling force, where the CCSP are collected via a first readout electrode electrically connected to the first remote doped area.

Stage 7720 includes maintaining, for the first sampling duration, voltages on the doped areas of a first group of readout structures that includes the rest of the multiple readout structures other than the first readout structure, such that a pulling force applied to charge carriers of the second polarity towards each of the remote doped areas of the first group of readout structures is less than half of the first pulling force.

Stage 7730 includes maintaining, for a second sampling duration that is later than the first sampling duration, relative voltages on the Ge photosensitive area, a second remote doped area of a second readout structure out of the multiple readout structures, and a second intermediary doped area of the second readout structure, such that charge carriers of the second polarity are forced to move from the Ge area toward the second readout structure by a second pulling force, where the CCSP are collected via a second readout electrode electrically connected to the second remote doped area.

Stage 7740 includes maintaining, for the second sampling duration, voltages on the doped areas of a second group of readout structures that includes the rest of the multiple readout structures other than the second readout structure, such that a pulling force applied to charge carriers of the second polarity towards each of the remote doped areas of the second group of readout structures is less than half of the second pulling force.

Stage 7750 includes maintaining, for a third sampling duration that is later than the second sampling duration, relative voltages on the Ge photosensitive area, the first remote doped area, and the first intermediary doped area, such that charge carriers of the second polarity are forced to move from the Ge area toward the first readout structure by a third pulling force, where the charge carriers of the second polarity are collected via the first readout electrode. and

Stage 7760 includes maintaining, for the third sampling duration, voltages on the doped areas of the first group of readout structures, such that a pulling force applied to charge carriers of the second polarity towards each of the remote doped areas of the first group of readout structures is less than half of the third pulling force.

Optionally, a first voltage applied to first intermediate doped area during the first sampling duration is at least ten times higher than any voltage applied to any intermediate doped area of the first group of readout structures averaged over the first duration.

Optionally, method 7700 may be executed concurrently for a plurality of photosites.

Optionally, method 7700 may further include providing during a discarding-duration voltages to multiple areas of the photosite for driving charge carriers of the second polarity toward an electrode via which the charge carriers are disposed of from the photosite without being read.

As aforementioned, different techniques may be used for determining depth based on outputs of one or more photosites. The discussion below discusses systems and methods which may be used for determining distances of objects in a FOV of a SWIR electrooptical system, as well as other electrooptical systems which are sensitive to other parts of the electromagnetic spectrum.

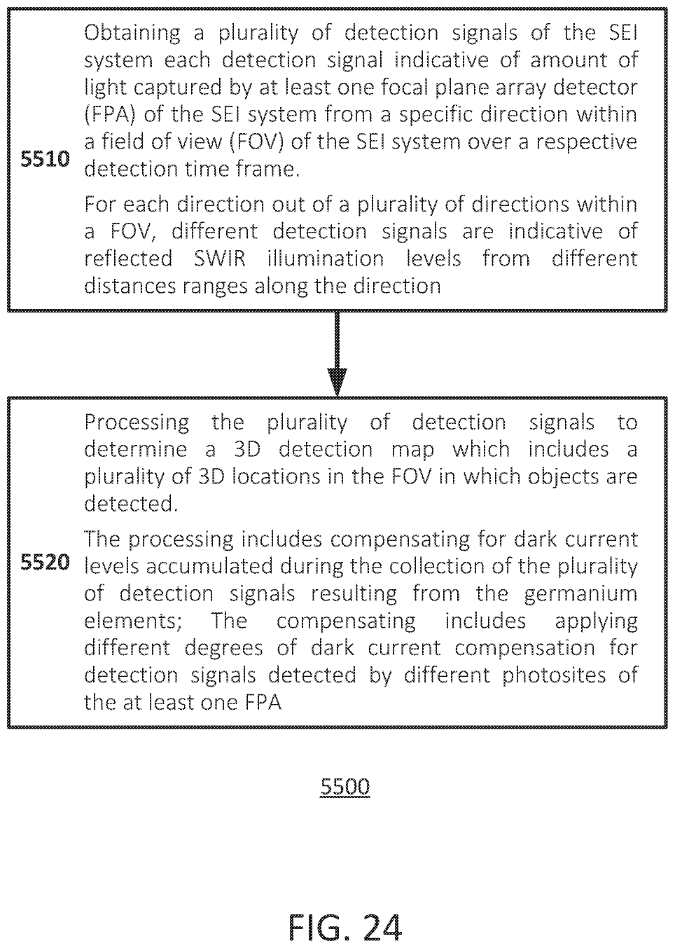

FIG. 24 illustrates a method 5500 for generating a depth image of a scene based on detections of a short-wave infrared (SWIR) electrooptical imaging system (SEI system), in accordance with examples of the presently disclosed subject matter. The SEI system may be any of the systems discussed above, or any other suitable SWIR electrooptical system (e.g., a sensor, a camera, a lidar, and so on). Method 5500 may be executed by one or more processors of the SEI system, one or more processor external to the SEI system, or a combination of both.

Stage 5510 includes obtaining a plurality of detection signals of the SEI system each detection signal indicative of amount of light captured by at least one FPA detector of the SEI system from a specific direction within a FOV of the SEI system over a respective detection time frame (i.e., the detection time frame during which the respective detection signal is captured, e.g., measured from the triggering of the illumination by an associated light source such as a laser). The at least one FPA includes a plurality of individual photosites, each photosite including a Ge element in which impinging photons are converted to detected electric charge. It is noted that method 5500 may be implemented for any type of photosites which characterized by a high dark current, even if not including Ge but rather other elements.

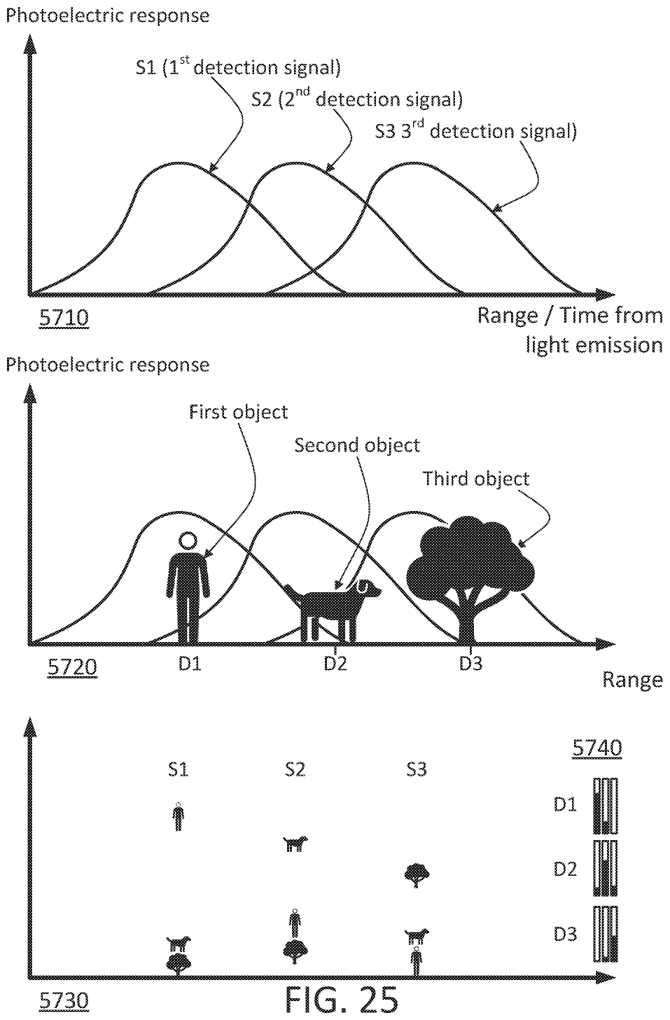

For each direction out of a plurality of directions within a FOV, different detection signals (out of the aforementioned plurality of detection signals) are indicative of levels of reflected SWIR illumination from different distances ranges along the direction. An example is provided in a diagram 5710 of FIG. 25, which illustrates the timing of three different detection signals arriving from the same direction within the FOV. The y-axis (ordinate) in the diagram is indicative of the level of response of the detection system to reflected photons arriving from the relevant directions. The reflected illumination originates in one or more light sources (e.g., lasers, LEDs) which are optionally controlled by the same processor which controls the FPA, and are reflected from a part of the FOV (e.g., corresponding to the spatial volume detectable by a single photosite). It is noted that different detection signals may be associated with similar but not fully overlapping parts of the FOV (e.g., if the sensor, the scene, or intermediate optics between the two is moving in time, detection signals from the same photosite may be reflected from somewhat different angles within the FOV at different detection time windows associated with the different detection signals.

Referring to the example of FIG. 25, it is noted that diagram 5710 does not show the detection level of each signal, but rather the response of the detection signals to photons reflected from a perfect reflector at different times from the initiation of light emission. Diagram 5720 illustrates three objects positioned at different distances from the SEI system. It is noted that in many instances, in each direction only one object is detected at each time, which is the object nearest to the SEI system. However, in some scenarios more than one object may be detected (e.g., if the foreground object is partly transparent, or not blocking light from the entire photosite). Diagram 5730 illustrates the levels of three returning signals in a direction in which one of the objects is present—in the example, a person in the near field, a dog in the middle range, and a tree in the far field (the selection of objects is arbitrary, and only light which is reflected from a portion from each object is usually detected by a single photosite). The light returning from an object in distance D1 is represented by the human figure for the three different detection signals (corresponding to different detection timing windows and to different ranges from the SEI system). Likewise, the levels of detection signals corresponding to light reflected from objects in distances D2 and D3 are represented by a dog and by a tree symbol, correspondingly. As shown in diagram 5740, reflections from an object positioned at a given distance can be translated to a tuple (or any other representation of the data, as any suitable form of direction-associated data-structure (DADS)) which is indicative of the relative levels of detected signals at different time windows. In the illustrated example, each number in the tuple is indicative of the detected signal level in one detection window. The indications of detection levels in the tuple may be corrected for distance from the sensor (as the reflected light from identical objects diminishes with the distance), but this is not necessarily so. While in the illustrated example three partly overlapping time windows where used, any number of time windows may be used. The number of time windows may be the same for different regions of the FOV, but this is not necessarily so.

Stage 5520 includes processing the plurality of detection signals to determine a three-dimensional (3D) detection map which includes a plurality of 3D locations in the FOV in which objects are detected. The processing includes compensating for dark current (DC) levels accumulated during the collection of the plurality of detection signals resulting from the Ge elements, and the compensating includes applying different degrees of dark current compensation for detection signals detected by different photosites of the at least one focal place array. Referring to the examples of the accompanying drawings, the different detection signals may be obtained at different times by different readout structures of any of the applicable photosites discussed above. Alternatively, the detection signals may be obtained by groups of interconnected photosites, as discussed at a greater detail below. Other implementations may also be used.

In addition to—or instead of compensating for accumulated dark current, the processing may include compensating for high integration noise levels and/or readout noise levels during the reading out of the plurality of detection signals. The compensating may include applying different degrees of noise levels compensation for detection signals detected by different photosites of the at least one focal place array.

The compensating for the collection of dark current, for the readout noise, and/or for the integration noise may be done in any suitable way, such as by using any combination of one or more of the following: software, hardware, and firmware. Especially, the compensation for the collection of dark current may be implemented using any combinations of any one or more of the systems, methods, and computer program products discussed above, or any parts thereof. Some non-limiting examples of the systems, methods, and computer program products which may be used for compensating for dark current and for applying degrees of dark current compensation for detection signals detected by different photosites of the at least one focal place array are discussed above with respect to FIGS. 12A-FIG. 35.

In some implementations, the compensating may be executed during the obtaining of the plurality of detection signals (e.g., in the hardware level of the sensor), and the processing may be executed on detection signals which are already compensating for dark current accumulation (e.g., as discussed in published patent applications by the applicant, TriEye LTD of Tel Aviv).

Referring to the compensating within stage 5520, optionally the compensating may include: subtracting a first dark current compensation offset from a first detection signal detected by a first photosite corresponding to a first detection range; and subtracting a second dark current compensation offset, that is different than the first dark current compensation offset, from a second detection signal detected by the first photosite corresponding to a second detection range which is further away from the SEI system than the first detection range.

Optionally, method 5500 may include coordinating of active illumination (e.g., by at least one light source of the SEI system) and the acquisition of the detection signals. Optionally, method 5500 may include: (a) triggering emission of first illumination (e.g., laser, LED) in coordination with initiating of an exposure of a first gated image in which a plurality of first detection signals are detected for different directions out of the plurality of directions; (b) triggering emission of second illumination (e.g., laser, LED) in coordination with initiating of an exposure of a second gated image in which a plurality of second detection signals are detected for the different directions; and (c) triggering emission of third illumination (e.g., laser, LED) in coordination with initiating of an exposure of a third gated image in which a plurality of third detection signals are detected for the different directions. In such a case, the processing of stage 5520 may optionally include: determining a presence of a first object in a first 3D location within a first direction out of the different directions based on at least one detection signal from each image out of the first image, the second image, and the third image, and determining a presence of a second object in a second 3D location within a second direction out of the different directions based on at least one detection signal from each image out of the first image, the second image, and the third image, wherein a distance of the first object from the SEI system is at least twice a distance of the second object from the SEI system.

Optionally, the applying of the different degrees of DC compensation for detection signals detected by different photosites of the at least one FPA may include using detected dark current levels of different reference photosites which are shielded from light arriving from the FOV.

Optionally, the compensating may include applying different degrees of DC compensation for detection signals detected concurrently by different photosites of the at least one FPA.

Referring to integration noise and to readout noise, it is noted that the compensation for such noises may be correlated by the at least one processor executing method 5500 to the number of illumination pulses used for illuminating parts of the FOV during the acquisition of the respective detection signals. The different number of illumination pulses may result in significant non-linearity of the detected signal, which is optionally corrected as part of the processing prior to the determining of the distance/3D location of different objects in the FOV.

Referring to the use of DADS for determining the distance/3D location for different objects in the FOV, it is noted that different translation functions of DADS (e.g., tuples) to distance may be used for different directions within the FOV, e., in order to compensate for non-uniformity of the detection channel across the FOV (e.g., of the sensor and/or the detection objects), for non-uniformity of illumination (e.g., using multiple light sources, light source non-uniformity or optics non-uniformity), and so on.

As mentioned above, different detection signals from the same direction within the FOV correspond to different detection windows, which may be of the same distance, or of different distances. For example, a detection window may correspond to a range of distances which is about 50 m (e.g., between 80 m from the SEI system and 130 m from the SEI system). In different examples, some or all of the detection windows used for determining a distance/3D location for an object in the FOV may be of a range of distances which is between 0.1 m-10 m, between 5 m-25 m, between 20 m-50 m, between 50 m-100 m, between 100 m-250 m, and so on. The distances ranges associated with different detection signals may overlap. For example, a first detection window may detect returning light from objects whose distances from the SEI system is between 0 m and 50 m, a second window may correspond to objects between 25 m and 75 m, and a third window may correspond to objects between 50 and 150 m.

Method 5500 may be executed by any one or more processors, such as, but not limited to, processors of any of the aforementioned systems. There is disclosed a system for generating a depth image of a scene based on detections of a short-wave infrared (SWIR) electrooptical imaging system (SEI system), the system including at least one processor configured to: obtain a plurality of detection signals of the SEI system each detection signal indicative of amount of light captured by at least one FPA detector of the SEI system from a specific direction within a FOV of the SEI system over a respective detection time frame, the at least one FPA including a plurality of individual photosites, each photosite including a Ge element in which impinging photons are converted to detected electric charge, wherein for each direction out of a plurality of directions within a FOV, different detection signals are indicative of reflected SWIR illumination levels from different distances ranges along the direction; and to process the plurality of detection signals to determine a three-dimensional (3D) detection map including a plurality of 3D locations in the FOV in which objects are detected, wherein the processing includes compensating for dark current (DC) levels accumulated during the collection of the plurality of detection signals resulting from the Ge elements, wherein the compensating includes applying different degrees of DC compensation for detection signals detected by different photosites of the at least one FPA.

Optionally, the compensating may include: subtracting a first DC compensation offset from a first detection signal detected by a first DE corresponding to a first detection range; and subtracting a second DC compensation offset, that is different than the first DC compensation offset, from a second detection signal detected by the first DE corresponding to a second detection range which is further away from the SEI system than the first detection range.

Optionally, the at least one processor may be further configured to: (a) trigger emission of first illumination in coordination with initiating of an exposure of a first gated image in which a plurality of first detection signals are detected for different directions out of the plurality of directions; (b) trigger emission of second illumination in coordination with initiating of an exposure of a second gated image in which a plurality of second detection signals are detected for the different directions; and (c) trigger emission of third illumination in coordination with initiating of an exposure of a third gated image in which a plurality of third detection signals are detected for the different directions. In such a case, the at least one processor may be further configured to determine, as part of the determining of the 3D detection map: (a) a presence of a first object in a first 3D location within a first direction out of the different directions based on at least one detection signal from each image out of the first image, the second image, and the third image, and (b) a presence of a second object in a second 3D location within a second direction out of the different directions based on at least one detection signal from each image out of the first image, the second image, and the third image, wherein a distance of the first object from the SEI system is at least twice a distance of the second object from the SEI system. The gated image (or equivalent thereof) may be achieved by utilizing the different readout structures of photosites of a PDA, e.g., in any of the ways discussed above.

Optionally, the applying of the different degrees of DC compensation for detection signals detected by different photosites of the at least one FPA includes using detected dark current levels of different reference photosites which are shielded from light arriving from the FOV. Optionally, the compensating may include applying different degrees of DC compensation for detection signals detected concurrently by different photosites of the at least one FPA. Optionally, one or more processors (and possibly all) out of the at least one processor may be part of the SEI system.

Referring to the aforementioned diagrams, method 5500 as well as any combination of two or more stages thereof may be executed by any of the processors discussed above with respect to the previous diagrams. Referring to the aforementioned diagrams, method 4600 as well as any combination of two or more stages thereof may be executed by any of the processors discussed above with respect to the previous diagrams. It is noted that while method 5500 and the associated systems were discussed in relation to generating depth images of scenes based on detections of SWIR electro optical imaging systems, similar methods and systems may be used mutatis mutandis for generating depth images of scenes based on detections of electro optical imaging systems which are characterized in high dark currents or other noise and interferences to the signals, even when operating in other parts of the electromagnetic spectrum.

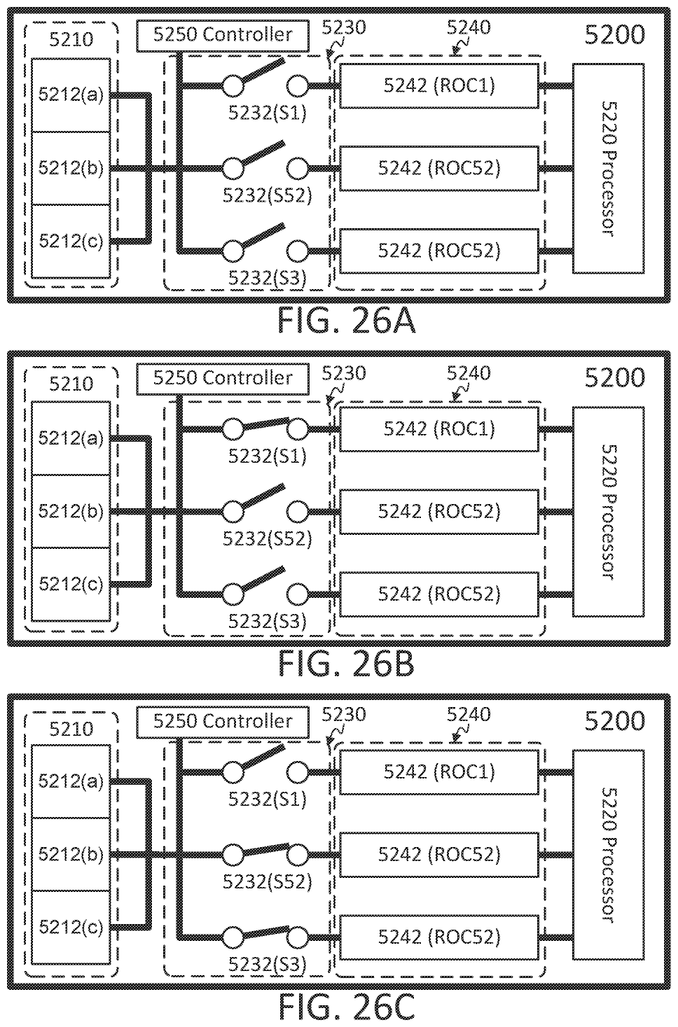

FIGS. 26A-26C illustrate sensor 5200 in accordance with examples of the presently disclosed subject matter. Sensor 5200 is operable to detect depth information of an object in its FOV. It is noted that sensor 5200 may be a variation of any of the sensors discussed above (under any term), with the adaptation discussed below (which include controller 5250 and its functionality, as well as the associated switches). Many of the details, options, and variations discussed above with respect to the different sensors are not repeated, for reasons of brevity, and may be implemented in sensor 5200, mutatis mutandis.

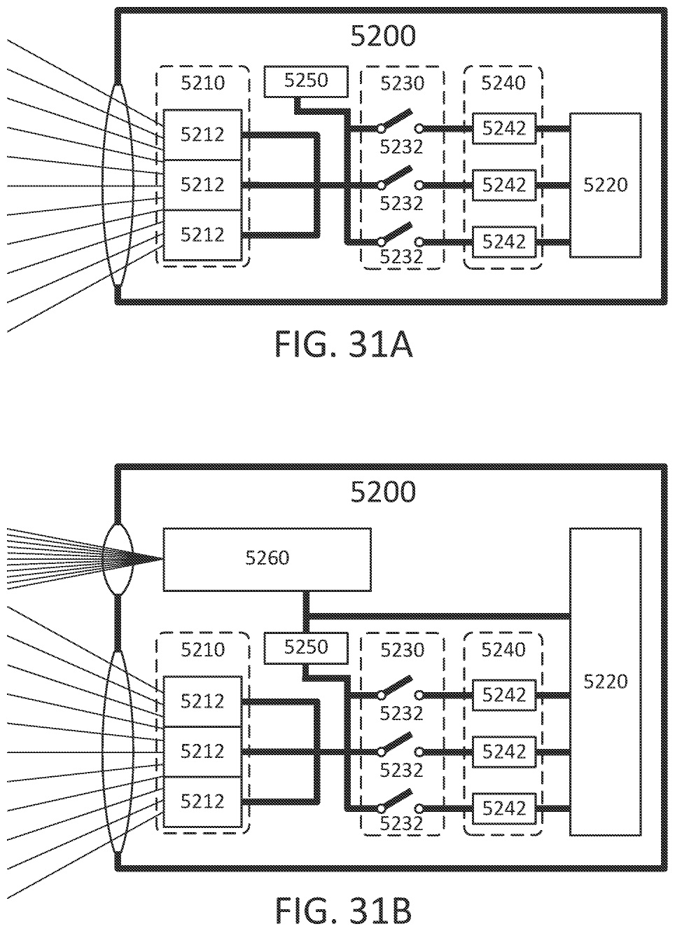

Sensor 5200 includes FPA 5290 which in turns includes a plurality of photosites 5212, each being operable to detect light arriving from an view IFOV of the PS. Different PSs 5212 are directed in different directions within a FOV 5390 of sensor 5200. For example, referring to FOV 5390 of FIG. 30, a first PS 5212(a) may be directed toward first IFOV 5312(a), a second PS 5212(b) may be directed toward second IFOV 5312(b), and a third PS 5212(c) may be directed toward third IFOV 5312(c). The part of FOV 5390 which is collectively detectable by a readout-group of PSs (collectively denoted 5210, including PSs 5212(a), 5212(b), and 5212(c)) is denoted 5310. It is noted that any type of PS 5312 may be implemented, e.g., including a single photodiode or a plurality of photodiode. The different PSs 5212 of a single readout-group 5210 (and optionally even of the entire FPA 5290) may be substantially duplication of one another, but this is not necessarily so, and different types of PSs 5212 may optionally be implemented in a single FPA 5290, and even in a single readout-group 5210. The different PSs 5212 of a single readout-group 5210 (and optionally even of the entire FPA 5290) may be sensitive to the same part(s) of the electromagnetic spectrum, or to different parts thereof. Any one or more of the types of PSs discussed elsewhere in this disclosure (e.g., above) may be implemented as PSs 5212.

It is noted optionally, all of the PSs 5212 of a single readout-group 5210 are physically adjacent to one another (i.e., each PS 4212 of a readout-group 5210 is physically adjacent to at least one other PS 5212 of the readout-group 5210, so as to create at least one continuous path through adjacent PSs 5212 between any two PSs 5212 of the readout-group 5210).

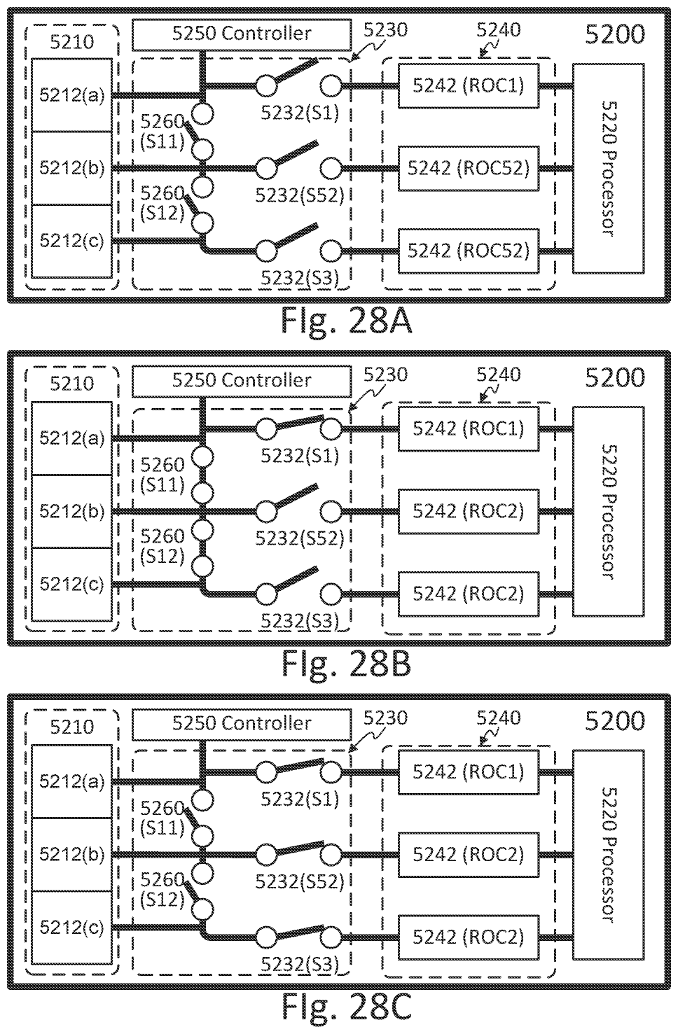

Nevertheless, non-continuous readout-groups may also be implemented (e.g., if some PSs 5212 of FPA 5290 are defective, if some PSs 5212 of FPA 5290 are unused (e.g., for saving power), or for any other reason. If FPA 5290 includes more than one readout-group 5210, the readout-groups 5210 may include the same number of PSs 5212 (but not necessarily so), may include the same type of PSs 5212 (but not necessarily so), may be arranged in the same geometrical configuration (e.g., in 1×3 arrays, as illustrated in the examples of FIGS. 28A and 28B; though not necessarily so).

Sensor 5200 includes at least one readout-set 5240 which includes multiple readout circuitries 5242. Each of the multiple readout circuitries 5242 in a single readout-set 5240 is connected to the same readout-group 5210 of PSs 5212 of FPA 5290 by a plurality of switches 5232 (collectively denoted 5230). A readout circuitry 5242 reads a signal from one or more PSs 5212 which are connected to the readout circuitry 5242, and outputs data (e.g., in an analog or digital manner) which is indicative of the levels of light to which the respective one or more PSs 5212 were subject. The outputted data may be provided to a processor, communicated to another system, stored in a memory module, or used in any other way. Different readout circuitries 5242 of the single readout-set are connected to the various PSs 5122 of the respective readout-group 5210 and operable to output an electric signal indicative of an amount of light impinging on the PSs 5212 of the readout-group 5210 when the readout group 5210 is connected to the respective readout circuitry 5242 via at least one of the plurality of switches 5230. It is noted that switches 5232 may be implemented in any suitable switching technology, such as any combination of one or more transistors. Switches 5232 may be implemented as part of FPA 5290, but this is not necessarily so. For example, some or all of switches 5232 may be included in a readout wafer which is electrically (and optionally also physically) connected to FPA 5290. Readout circuits 5242 may be implemented as part of FPA 5290, but this is not necessarily so. For example, some or all of readout circuits 5242 may be included in a readout wafer which is electrically (and optionally also physically) connected to FPA 5290.

In addition, sensor 5200 also includes at least one controller 5250, which is configured and operable to change switching states of the plurality of switches 5230, such that different readout circuits 5242 of the readout-set 5240 are connected out to the readout-group 5210 (i.e., to the PSs 5212 of the readout group 5210) at different times, for exposing different readout circuits 5242 to reflections of illumination light from objects located at different distances from sensor 5200. Illumination light may be emitted by a light source 5260 included in the sensor 5200 or in any electrooptical system in which sensor 5200 is implemented (e.g., a camera, a telescope, a spectrometer). Illumination light may also be emitted by another light source which is associated with sensor 5200 (whether it is controlled by it or by a common controller with it), or by any other light source.

Sensor 5200 also includes a processor 5220 configured to obtain the electric signals from the readout-set 5240 indicative of detected levels of reflected light collected from the IFOVs of the PSs 5212 of the readout-group 5210, for determining depth information for the object, indicative of a distance of the object from the sensor 5200. Such an object may be, for example, tower 5382 in the background of FOV 5390, or tree 5384 in the foreground of FOV 5390. For example, processor 5200 may implement method 5500, or any technique described above (e.g., with respect to FIGS. 24 and 37).

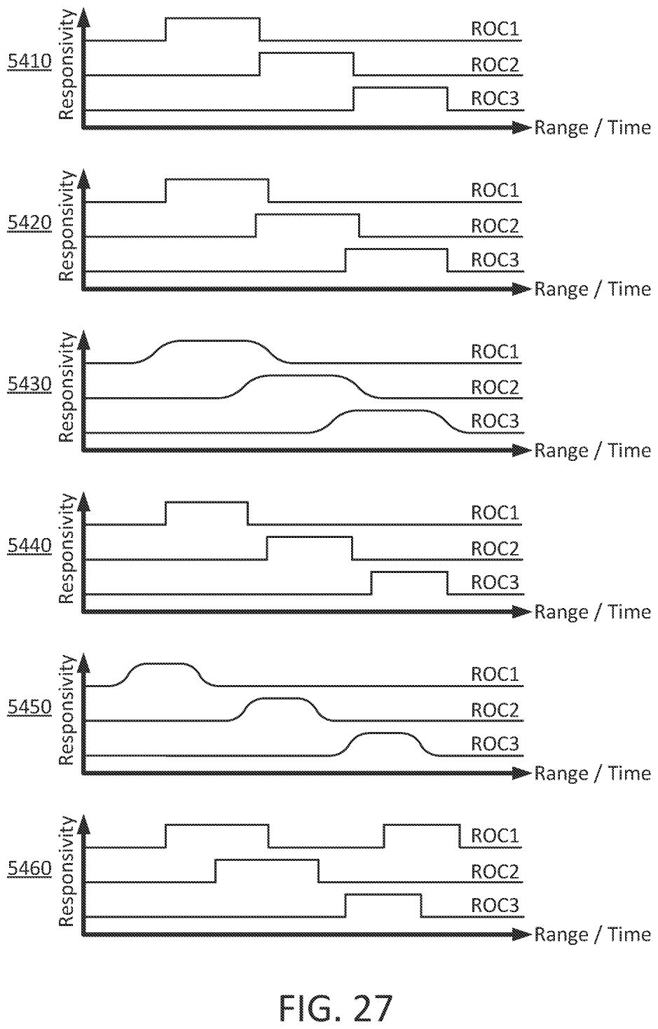

FIGS. 26A, 26B, and 26C illustrate the same sensor 5200 in different switching states of readout-set 5240, which is connected to a readout-group 5210, which includes in the illustrated example three PSs—5212(a), 5212(b), and 5212(c). In FIG. 38A, no readout circuitry 5242 is connected to any PS 5212, in which case no reading out is possible. In FIG. 38B, a single readout circuitry 5242(a) is connected to all three PSs 5212 of the readout-group 5210, enabling reading of signal indicative of light impinging on all three PSs 5212 by a single readout circuitry 5242. For example, at different times during a sampled frame, all of the PSs 5212 may be sequentially connected to one readout circuit 5242 at a time, so that in all times light is collected by all of the PSs 5212 of the readout-group 5210 is measured, but by different readout circuitries 5242 at different times. Such an example is provided in diagram 5410 of FIG. 27.

In FIG. 26C, a proper subgroup of multiple readout circuities (including in the illustrated example readout-circuitries 5242(b) and 5242(c)) is connected to all of the PSs 5212 of the readout-group 5210, enabling reading of signal indicative of light impinging on all three PSs 5212 by multiple readout circuitries 5242. Connecting two readout circuitries 5212 to the readout-group 5210 is exemplified in diagrams 5420 and 5430 of FIG. 27. Depending on the requirements of implementations, more than two readout circuitries 5212 may optionally be connectable to the readout-group 5210. An example for implementation of connection of multiple readout circuitries 5212 to a single readout-group 5210 is in transition times between two different detection time windows of different detection signals (e.g., as discussed with respect to FIGS. 24 and 25 above).

For example, at different times during a sampled frame, all of the PSs 5212 may be sequentially connected to one readout circuit 5242 at a time, so that in all times light is collected by all of the PSs 5212 of the readout-group 5210 is measured, but by different readout circuitries 5242 at different times. Such an example is provided in diagram 5410 of FIG. 27. In other examples, in some times only one readout circuit 5242 is connected to the PSs 5212 of the readout group 5210, while more than one readout circuit 5242 is connected in parallel to the PSs 5212 of the readout group 5210. Such an examples are provided in diagrams 5420 and 5430 of FIG. 27. In yet other examples, different subsets of multiple readout circuits 5242 may be connected in parallel to the PSs 5212 of the readout group 5210 at different times. With respect to all of the options, it is noted that optionally, there may be idle times in which none of the readout circuits 5242 is connected to any of the PSs 5212 of the readout group 5210. Such examples are provided in diagrams 5440 and 5450 of FIG. 27. Diagram 5460 of FIG. 27 exemplified situations in which different combinations of connections are implemented in a single frame—a single readout circuit 5242, a plurality of readout circuits 5242, and no readout circuits 5242 being connected to the readout group 5210 in different times during a detection duration of the sensor.

FIGS. 28A-28C illustrate sensor 5200 in accordance with examples of the presently disclosed subject matter. Optionally, switching network 5230 includes switchable circuitry which also enables individual readout circuits 5242 to be connected to individual PSs 5212 at certain times, while being concurrently connected to a plurality of PSs 5212 at other times. In the illustrated examples, in FIG. 28B readout circuit 5242(ROC1) is connected to all three PSs 5212(a), 5212(b), and 5212(c), while in FIG. 28C the same readout circuit 5242(ROC1) is connected to only one PS 5242(a), while the other two readout circuitries 5242(ROC2) and 5242(ROC3) are connected to a single PS 5212 each. It is noted that operational parameters of detection (e.g., photodiode bias, amplification gain, etc.) may differ in these two states of detection, for example, in order to handle different amounts of light collected by different amount of PSs 5212.

Sensor 5200 is operable to detect depth information of an object in its FOV. it is noted that sensor 5200 may be a variation of any of the sensors discussed above (under any term), with the adaptation discussed below (which include controller 5250 and its functionality, as well as the associated switches). Many of the details, options, and variations discussed above with respect to the different sensors are not repeated, for reasons of brevity, and may be implemented in sensor 5200, mutatis mutandis.

In addition, sensor 5200 may also be operate in other detection modes, providing detection outputs which do not include depth information. For example, in some detection modes sensor 5200 may operate as a camera, providing a 2D image in which different detection values are indicative of amount of light reflected from a part of the FOV within one (or more) detection duration. It is noted that such detection modes may involve active illumination of the FOV, but this is not necessarily so.

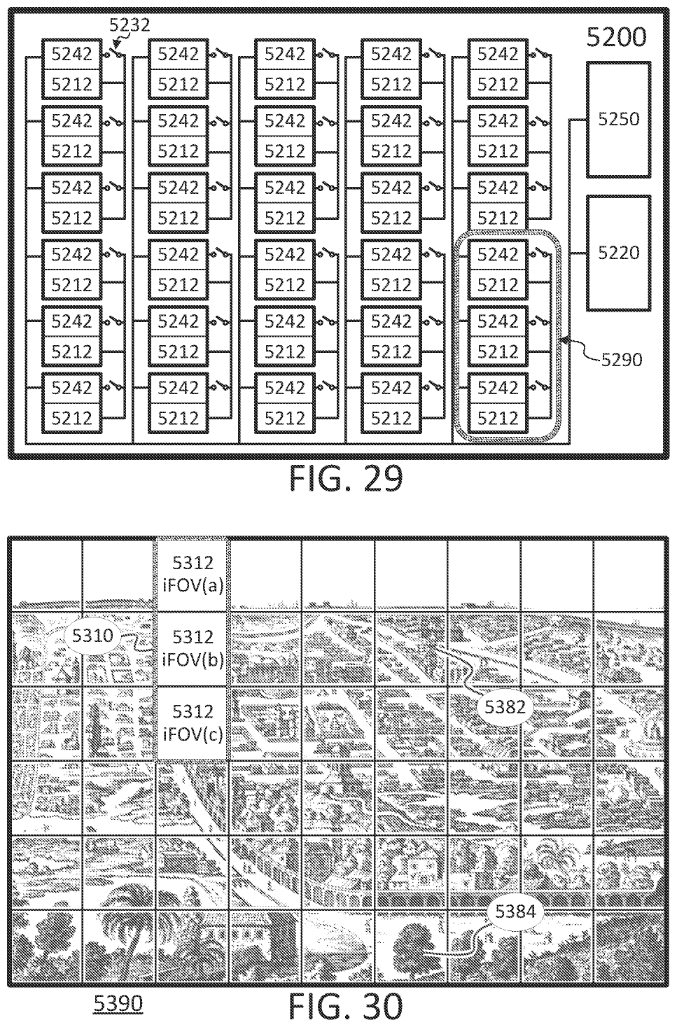

FIG. 29 illustrates sensor 5200 in accordance with examples of the presently disclosed subject matter. As in other diagrams of sensor 5200, it is clear that the number of PSs 5212 in the sensor may differ greatly from the example illustration, and may be, for example, in the range of thousands, millions, etc.

FIG. 30 illustrates a FOV 5390 of an electrooptical system, and a plurality of instantaneous FOVs 5312, in accordance with examples of the presently disclosed subject matter.

FIGS. 31A and 31B illustrate various examples of sensor 5200, in accordance with examples of the presently disclosed subject matter. In the examples of FIGS. 31A and 31B, rays of light arriving from the FOV towards a readout-group of PSs (collectively denoted 5210) is illustrated, as well as optional rays of light emitted from an optional light source 5260 towards the FOV. As in other diagrams of sensor 5200, it is clear that the number of PSs 5212 in the sensor may differ greatly from the example illustration, and may be, for example, in the range of thousands, millions, etc.

Referring to sensor 5200, and to the systems, methods, and sensors discussed with respect to FIGS. 24 through 31B, it is noted that PSs which include a plurality of readout structures (also referred to as “readout compounds”) may be implemented instead of a plurality of PS s, to detect signals indicative of light arriving at different times from an instantaneous FOV. For example, a first readout structure (such as readout structure 6570, 9030, or even floating diffusion 7540 acting as a readout structure) may be used to detect signal 51 of FIG. a second readout structure of the same PS may be used to detect signal S2 of FIG. 25, and a third readout structure of the same PS may be used to detect signal S3 of FIG. 25. For any system and any method which utilize combinations of multiple PSs to detect signals from the same part of the FOV at different times which is discussed with respect to FIGS. 24 through 31B, an equivalent system or method may be implemented which utilize multiple readout structures of any single PS of the ones disclosed in the present disclosure for detecting signals from the same part of the FOV at different times, mutatis mutandis.

Referring to all PSs discussed above and throughout the present disclosure, any of those PSs may optionally include a guard ring (not illustrated) or trenching, completely, incompletely, or partly surrounding the PS (or parts thereof). Such partial or complete trenching or guard ring are not illustrated in the diagrams for reasons of clarify and simplicity of the diagrams. Many uses and ways of implementations are known to a person who is of skilled in the art, and are not disclosed here for reasons of brevity.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to disclosures containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the disclosure have been illustrated and described herein, many modifications, substitutions, changes, and equivalents will now occur to those of ordinary skill in the art. It is, therefore, to be understood that the appended claims are intended to cover all such modifications and changes as fall within the true spirit of the disclosure. It will be appreciated that the embodiments described above are cited by way of example, and various features thereof and combinations of these features can be varied and modified. While various embodiments have been shown and described, it will be understood that there is no intent to limit the disclosure by such disclosure, but rather, it is intended to cover all modifications and alternate constructions falling within the scope of the disclosure, as defined in the appended claims.

1. An infrared (IR) photodetecting system operable to detect IR radiation, the photodetecting system comprising:
at least one photosite (PS), the at least one PS comprising a germanium (Ge) photosensitive area, operable to generate electron-hole pairs in response to impinging IR photons, the Ge photosensitive area comprising an absorber doped area having a first polarity, and a silicon (Si) layer comprising a diode, the diode comprising a first doped area of the first polarity and a second doped area of a second polarity opposite to the first polarity, wherein the first doped area is located between the second doped area and the absorber doped area;
at least one power source, operable to provide a first area voltage to the first doped area and to provide a second area voltage to the second doped area; and
a controllable power source operable to provide to the Ge photosensitive area for a sampling duration of the PS an activation voltage which forces charge carriers of the second polarity (CCSP) to move from the Ge photosensitive area toward the photodiode where the CCSP are collected via a readout electrode electrically coupled to the second doped area, and to provide to the Ge photosensitive area, upon ending of the sampling duration, a rest voltage which diminishes the forcing of the CCSP toward the photodiode, thereby ceasing the collection of signals by the PS.

2. The IR photodetecting system of claim 1, wherein an amplitude of the rest voltage is at least ten times lower than an amplitude of the activation voltage.

3. The IR photodetecting system of claim 1, wherein the sampling duration is shorter than 10 nanoseconds.

4. The IR photodetecting system of claim 1, wherein IR photons from a field of view of the IR photodetecting system pass through the Si layer before being absorbed in the Ge photosensitive area.

5. The IR photodetecting system of claim 1, further comprising a passivation layer between (a) the Ge photosensitive area and the photodiode and (b) the at least one power source.

6. An electro-optical detection system comprising the IR photodetecting system of claim 1 and comprising:
a plurality of photosites;
at least one optical interface for directing light from a field of view of the electro-optical detection system onto the IR photodetecting system;
readout circuitry operable to read from each of the plurality of photosites at least one electric signal corresponding to a number of photons captured by the Ge photosensitive area during the sampling duration of the respective photosite; and
a processor operable to process detection data provided by the readout circuitry that is indicative of the plurality of electric signals, to provide an IR image of the field of view.

7. The electrooptical detection system of claim 6, wherein the processor is further configured to process the detection data to determine a presence of at least one object in the field of view.

8. An infrared (IR) photodetecting system operable to detect IR radiation, comprising:
at least one photosite comprising a Ge photosensitive area, operable to generate electron-hole pairs in response to impinging IR photons, the Ge photosensitive area comprising an absorber doped area having a first polarity and a silicon (Si) layer comprising a first doped area, a storage well, a floating diffusion, and a transfer gate;
at least one controllable power source, operable to modulate voltage to at least one of the first doped area, the Ge photosensitive area and the floating diffusion; and
a controller operable to control the at least one controllable power source and the transfer gate, to provide at one time voltages to the Ge photosensitive area, to the first doped area, and to the floating diffusion, thereby forcing charge carriers of the second polarity (CCSP) to move from the Ge photosensitive area toward the storage well, to provide at another time other voltages to the Ge photosensitive area, to the first doped area and to the floating diffusion, thereby diminishing the forcing of the CCSP toward the storage well, thereby ceasing the collection of signals by the storage well, and to intermittently transfer charge carriers of the second polarity from the storage well via the transfer gate to the floating diffusion, where the charge carriers are read via a readout electrode electrically coupled to the floating diffusion.

9. The IR photodetecting system of claim 8, wherein the storage well is pinned at least partly below a pinning layer of the opposite polarity.

10. The IR photodetecting system of claim 8, wherein during the other time, charge carriers of the second polarity are disposed of from the photosite without being read.

11. The IR photodetecting system of claim 8, wherein the storage well is positioned between the first doped area and the floating diffusion.

12. The IR photodetecting system of claim 8, wherein the first doped area is positioned between the storage well and the Ge photosensitive area.

13. The IR photodetecting system of claim 8, wherein the sampling duration is shorter than 10 nanoseconds.

14. The IR photodetecting system of claim 8, wherein IR photons from a field of view of the IR photodetecting sensor system pass through the Si layer before being absorbed in the Ge photosensitive area.

15. The IR photodetecting system of claim 8, further comprising a passivation layer between (a) the Ge photosensitive area and the photodiode and (b) the at least one power source.

16-20. (canceled)

21. A method for detecting infrared (IR) radiation, comprising:
providing a first area voltage to a first doped area of a photosite (PS) and providing a second area voltage to a second doped area of the PS that comprises a germanium (Ge) photosensitive area, operable to generate electron-hole pairs in response to impinging IR photons, the Ge photosensitive area comprising an absorber doped area having a first polarity, the PS further comprising a silicon layer comprising a diode, the diode comprising the first doped area of the first polarity and the second doped area of a second polarity opposite to the first polarity, wherein the first doped area is located between the second doped area and the absorber doped area;
while providing the first area voltage and the second area voltage, providing to the Ge photosensitive area for a sampling duration of the photosite an activation voltage that forces charge carriers of the second polarity (CCSP) to move from the Ge photosensitive area toward the photodiode where the CCSP are collected via a readout electrode electrically coupled to the second doped area; and
upon ending of the sampling duration, providing to the Ge photosensitive area a rest voltage that diminishes the forcing of the CCSP toward the photodiode, thereby ceasing the collection of signals by the photosite.

22. The method of claim 21, wherein the photosite is the photosite of an IR photodetector system.

23. A method for detecting infrared (IR) radiation, comprising:
modulating a voltage to at least one area of a photosite (PS), the area selected from the group consisting of a first doped area of the PS, a germanium (Ge) photosensitive area of the PS and a floating diffusion of the PS, wherein the PS comprises at least (a) the Ge photosensitive area that is operable to generate electron-hole pairs in response to impinging IR photons and which comprises an absorber doped area having a first polarity and (b) a silicon layer comprising the first doped area, a storage well, the floating diffusion, and a transfer gate, wherein the modulating comprises:
at one time, providing some voltages to the Ge photosensitive area, to the first doped area, and to the floating diffusion, thereby forcing charge carriers of the second polarity (CCSP) to move from the Ge photosensitive area toward the storage well,
at another time, providing other voltages to the Ge photosensitive area, to the first doped area, and to the floating diffusion, thereby diminishing the forcing of the CCSP toward the storage well, thereby ceasing the collection of signals by the storage well, and
intermittently transferring charge carriers of the second polarity from the storage well via the transfer gate to the floating diffusion, where the CCSP are read via a readout electrode electrically coupled to the floating diffusion.

24. The method of claim 23, wherein the photosite is the photosite of an IR photodetector.

25. The method of claim 23, wherein an amplitude of the rest voltage is at least ten times lower than an amplitude of the activation voltage.

26-33. (canceled)
